(19) United States
(12) Patent Application Publication
(10) Pub. No.: US 2022/0328500 A1
(43) Pub. Date: Oct. 13, 2022

(54) High Density 3 Dimensional Gate All Around Memory

(71) Applicant: Taiwan Semiconductor Manufacturing Company, Ltd., Hsinchu (TW)

(72) Inventor: Chung-Liang Cheng, Changhua County (TW)

(21) Appl. No.: 17/393,381

(22) Filed: Aug. 3, 2021

Related U.S. Application Data
(60) Provisional application No. 63/173,125, filed on Apr. 9, 2021.

(51) Int. Cl. H01L 27/1159; H01L 29/06; H01L 29/423; H01L 29/78; H01L 29/786; H01L 21/02; H01L 29/66

(52) U.S. Cl. CPC H01L 27/1159; H01L 29/0665; H01L 29/42392; H01L 29/78391; H01L 29/78696; H01L 21/0259; H01L 29/6684; H01L 29/66742

(57) ABSTRACT

Methods of fabricating a semiconductor devices are disclosed. The method include forming a transistor device in a first device region on the semiconductor device, and forming a memory device in a second device region on the semiconductor device, the memory device being connected to the transistor device. In some embodiments, forming the memory device includes forming a first bit line, forming a first word line connected to the first bit line, forming a plate line connected to the first word line and the first bit line, forming a second bit line connected to the plate line, and forming a second word line connected to the second bit line and the plate line.

### PRIORITY CLAIM AND CROSS-REFERENCE

This application claims the benefit of U.S. Provisional Patent Application No. 63/163,742, titled “THREE-DIMENSIONAL MEMORY DEVICE STRUCTURES AND METHODS,” filed Mar. 19, 2021, U.S. Provisional Patent Application No. 63/163,769, titled “THREE-DIMENSIONAL MEMORY DEVICE STRUCTURES AND METHODS,” filed Mar. 19, 2021, and U.S. Provisional Patent Application No. 63/173,125, titled “High Density 3 Dimensional Gate All Around Memory” filed Apr. 9, 2021.

### BACKGROUND

With advances in semiconductor technology, there has been increasing demand for faster devices and higher storage capacity. To scale down the transistors, the semiconductor industry continues to scale down the dimensions of semiconductor devices, such as fin field effect transistors (finFETs) that include semiconductor fins with high aspect ratios in which channel and source/drain regions are formed. A gate structure is formed over and along the sides of the fin (e.g., wrapping), providing the advantage of the increased surface area of the channel.

To scale down memory cells, the semiconductor industry has been reducing lateral device dimensions to reduce device size, while increasing the vertical dimension to increase memory charge storage. The semiconductor industry has also been exploring new architecture and new materials for improved memory performance.

Such scaling down has increased the complexity of semiconductor manufacturing processes. Since device feature sizes continue to decrease, fabrication processes continue to become more difficult to perform. Therefore, improved memory device technology is highly desirable.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes and their structure allows them to be aggressively scaled while maintaining gate control and mitigating SCEs. In conventional processes, GAA devices provide a channel in a silicon nanowire. However, integration of fabrication of the GAA features around the nanowire can be challenging. For example, while the current methods have been satisfactory in many respects, challenges with respect to forming strain enhancement, source/drain formation, and other features creating the current methods to not be satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features in the figures are not drawn to scale. In fact, the dimensions of the various features may be arbitrarily increased or reduced for clarity of discussion.

FIGS. 1A and 1B illustrate a cross-sectional view and a three-dimensional (3D) view of intermediate structures at an early stage of an exemplary method for fabricating semiconductor devices in device regions 1 and 2, respectively, in accordance with some embodiments.

FIGS. 2, 3, 4, 5A, and 5B illustrate cross-sectional views of respective intermediate structures at various stages of an exemplary method for fabricating semiconductor devices in device regions 1 and 2, respectively, in accordance with some embodiments.

FIGS. 6, 7, 8, 9, 10, 11, 12, and 13 illustrate cross-sectional views of respective intermediate structures at various stages of an exemplary method for fabricating semiconductor devices in device regions 1 and 2, respectively, in accordance with some embodiments.

FIGS. 14-17 illustrate cross-sectional views of respective intermediate structures at various stages of an exemplary method for fabricating semiconductor devices including a 3D GAA transistor and a 3D GAA memory cell, in accordance with some embodiments.

FIG. 18A-C illustrates a cross-sectional view, a top view and a schematic diagram of a memory device having a ferroelectric memory element.

FIG. 19 illustrates a semiconductor device having a 2 bit FeRAM cell sharing a common plate line.

FIG. 20 is a simplified flowchart illustrating a method of fabricating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A one-transistor one-capacitor (1T1C) memory cell is a type of memory comprising a capacitor and a transistor. The capacitor stores varying levels of charge which correspond to an individual bit of data stored in the capacitor, and the transistor facilitates access to the capacitor for read and write operations. The relatively simple structure of the 1T1C memory cell allows high memory density, which leads to high memory capacity and a low cost per bit. 1T1C memory cells may be used with dynamic random-access memory (DRAM).

However, as DRAM is reaching performance limits, it becomes volatile, may have high power consumption, and depend upon complex refresh circuitry. When DRAM becomes volatile, it may be unable to store data in the absence of power. A promising new memory device that may perform better than DRAM is ferroelectric random-access memory (FeRAM). Ferroelectrics are a class of materials that consist of crystals exhibiting spontaneous electrical polarization. They can be in two states, which can be reversed with an external electric field. When such a field is applied, the electric dipoles formed in the crystal structure of the ferroelectric material tend to align themselves with the field direction. After the field is removed, they retain their polarization state—giving the material its non-volatile characteristic. A ferroelectric material has a non-linear relationship between the applied electric field and the polarization charge, giving the ferroelectric polarization-voltage (P-V) characteristic the form of a hysteresis loop.

FeRAM is generally referred to as a DRAM like memory with ferroelectrics implemented as dielectric in a capacitor part of the memory. In contrast with DRAM, FeRAM has lower power consumption, the potential for better performance, does not depend upon complex refresh circuitry, and is non-volatile. FeRAM memory cells typically include a transistor and a ferroelectric capacitor structure, which includes a ferroelectric structure sandwiched between a top electrode and a bottom electrode. The FeRAM memory cell is configured to store a bit of data, depending on how atoms are aligned relative to one another in the ferroelectric capacitor structure. For example, a first state of a FeRAM memory cell in which atoms in the ferroelectric structure are polarized in an “up” direction may represent a binary value of “1”, whereas a second state of the FeRAM memory cell in which atoms in the ferroelectric structure are polarized in a “down” direction may represent a binary value of “0”, or vice versa.

However, issues with complex ferroelectric materials have presented significant challenges. Early attempts were based on ferroelectric materials belonging to the perovskite family of lead-zirconate-titanate (PZT). But conformally depositing these materials in thin layers has proven very challenging. Also, the very high dielectric constant of these materials (in the order of 300) posed an obstacle for integrating them into a functional transistor.

Discovery of a ferroelectric phase in hafnium-oxide (HfO2) has however triggered some new ideas in manufacturing memory devices comprising FeRAM. It has been discovered that an orthorhombic crystal phase—the ferroelectric phase—that can be stabilized by doping HfO2 with e.g. silicon (Si). Compared to PZT, HfO2 has a lower dielectric constant and can be deposited in thin layers, in a conformal way. On top of that, HfO2 is material that has been used as the gate stack dielectric material in logic devices. By modifying this CMOS-compatible material, the logic transistor can now be turned into a non-volatile FeFET memory transistor.

Functional FeFETs have already been demonstrated in two-dimensional, planar architectures. But the ability to make conformal layers of HfO2 opens the door towards vertical varieties, e.g. by depositing the ferroelectric material on a vertical ‘wall’ and stacking the transistors in a third dimension. On the material side, these 3D FeFETs can solve some of the challenges imposed by 2D FeFET structures. One challenge has to do with the poly-crystalline nature of the HfO2 dielectric. Scaling the dimensions of the HfO2 layer significantly limits the number of crystal grains within the layer. Not all these grains have the same polarization direction, and this impacts their response on the external electric field—leading to large variabilities. By going 3D, this restriction is at least removed in the third dimension, relaxing the variability and allowing a better control of the statistics.

In accordance with the present disclosure, a novel process for manufacturing devices is provided. In some embodiments, fabrication of the memory device includes fabricating one or more of a FeRAM cell. The FeRAM cell, in those embodiments, is a multi-bit cell sharing common plate lines (ground lines, “PL” herein-after). The sharing of the common PL by the multi-bit FeRAM cell in those embodiments improves dimension density of memory devices when they are stacked 3D during manufacturing, improves memory device performance and/or provides any other benefits.

In accordance with the present disclosure, a novel multi-bit FeRAM included in a memory device is provided. In some embodiments, the multi-bit FeRAM comprise one or more common PLs, which improves a dimension density of the memory device when manufactured with other memory devices on a substrate wafer. In one embodiment, the multi-bit FeRAM is a 2 bit cell including one common PL between the 2 cells.

In some embodiments, the multi-bit FeRAM cell included in the memory device has a gate-all-around (GAA) structure having a first electrode and a dielectric material wrapped around a second electrode. In those embodiments, the dielectric material for the FeRAM cell includes high-k and ferroelectric materials. In those embodiments, the FeRAM cell is formed as a passive device of the memory device. In those embodiments, the memory device includes a transistor device. In those embodiments, the transistor device is a GAA transistor having a gate electrode and gate dielectric wrapped around the channel regions of the transistor. In those embodiments, the GAA transistor are used in the processor core, input/output, or static random access memory (SRAM). The memory device is referred to, in those embodiments, GAA FeRAM. In those embodiments, multiple GAA FeRAMs are stacked 3D and thus are referred to as a 3D GAA FeRAM structure.

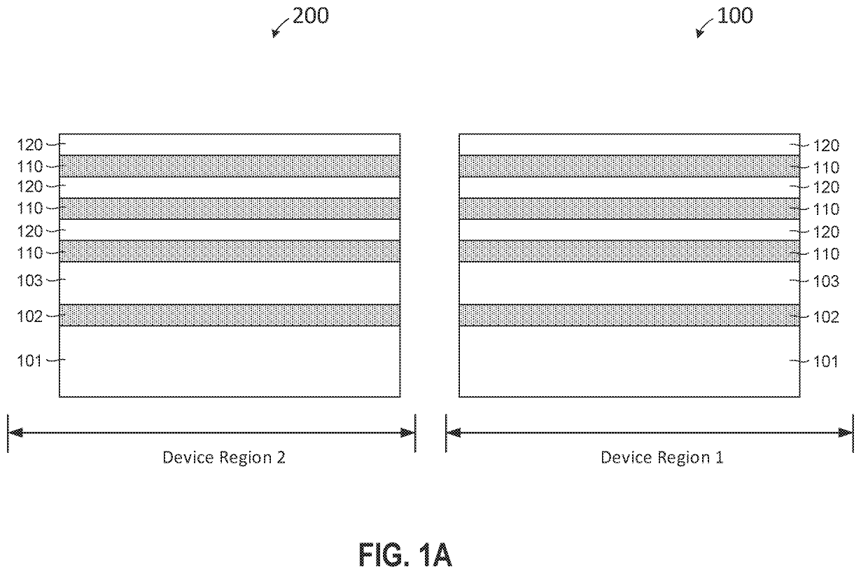

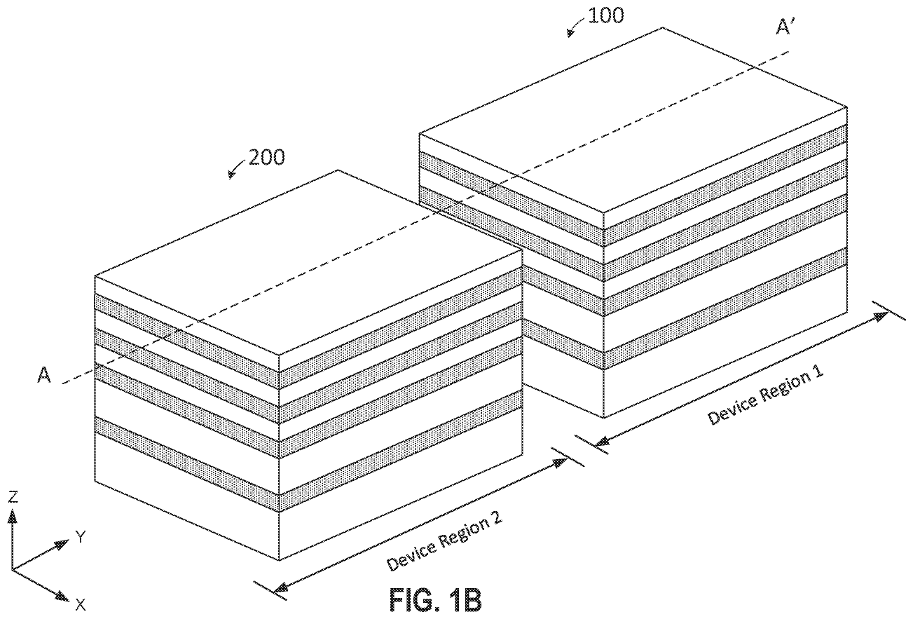

FIGS. 1-17 illustrate an example process of manufacturing an example memory device including a FeRAM cell in accordance with the present disclosure. In these figures, to simplify the drawings, common elements are identified with the same reference numerals. Further, for intermediate device structures in successive processing stages of the example process, reference numerals are only used to mark changes from the previous stage, unless otherwise noted. It should be understood, although only one FeRAM cell is illustrated in these figures, it is not intended to limit the present disclosure only to a memory device having only one FeRAM cell. It is understood that a memory device in accordance with the present disclosure can have more than one FeRAM cell.

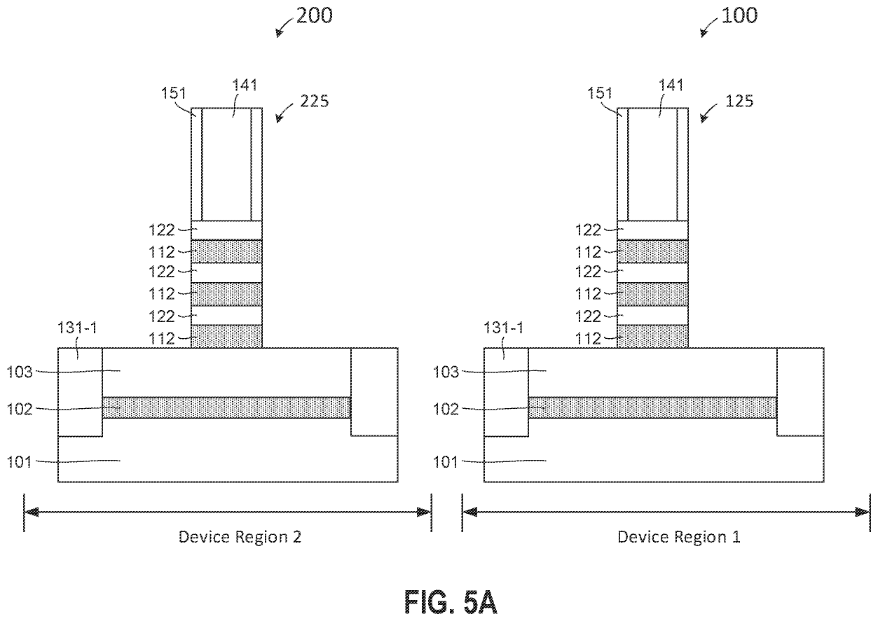

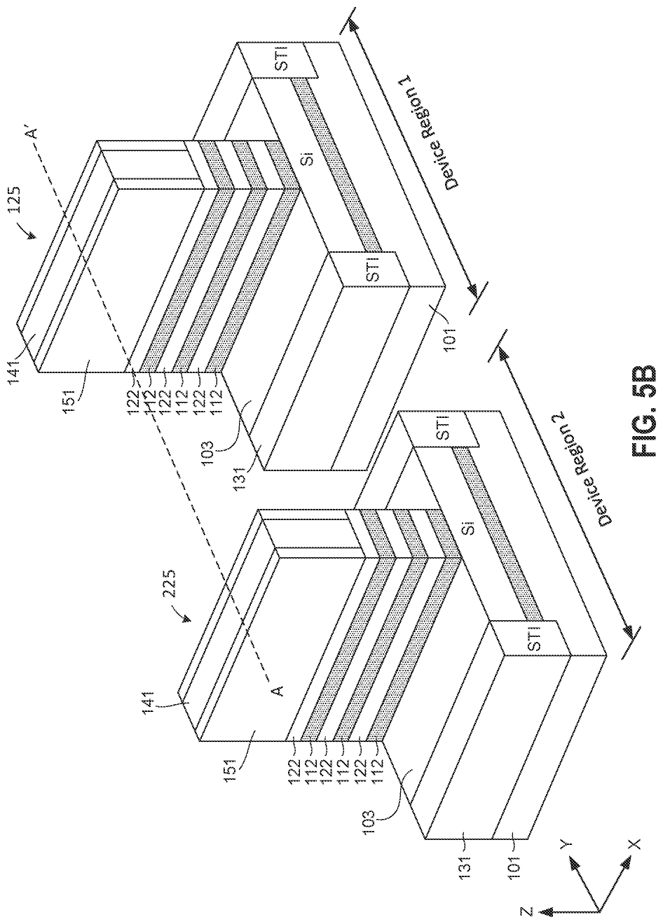

FIGS. 1A and 1B illustrate a cross-sectional view and an example three-dimensional (3D) view of intermediate structures at an early stage of the example process for fabricating the example memory device including a FeRAM cell. As can be seen, for fabricating the example memory device, two device regions (device region 1 and device region 2 as shown) are formed in this example process. FIG. 1A illustrates a cross-sectional view of the device regions, and FIG. 1B illustrates a three-dimensional view of the device regions. The cross-sectional view in FIG. 1A is taken along the A-A′ cutline in FIG. 1B. FIG. 1B also shows a second cutline B-B′ perpendicular to cutline A-A′, which is referred to in subsequent drawings, e.g., in FIGS. 5B, 14A, 14B, 15A, 15B, 16A, and 16B.

In the subsequent figures, intermediate device structures at various stages of fabricating semiconductor devices in device in regions 1 and 2 are referred to as device structures 100 and 200, respectively. In some embodiments, intermediate device structures 100 and 200 are fabricated concurrently on the same semiconductor wafer and in the same integrated circuit (IC) chip. However this is not necessarily the only case. In some embodiments, they are fabricated separately and non-concurrently.

As shown in FIGS. 1A and 1B, the intermediate structures 100 and 200 include stacked structures in the first and second device regions on a substrate, respectively. Each of the stacked structures includes a stack of alternating first and second semiconductor layers 110 and 120. In some embodiments, the substrate is a bulk semiconductor substrate. In some embodiments, the substrate is semiconductor-on-insulator (SOI) substrate, which may be doped (e.g., with a p-type or an n-type dopant) to form various well regions or doped regions therein, or may not doped. In those embodiments, the SOI substrate may include a layer of a semiconductor material formed on an insulator layer. The insulator layer may be a buried oxide (BOX) layer, a silicon oxide layer, or the like. The insulator layer is provided on a silicon or glass substrate. The substrate may be made of silicon or another semiconductor material. For example, the substrate may be a silicon wafer.

In some embodiments, the substrate is made of a compound semiconductor such as silicon germanium (SiGe), silicon carbide (SiC), gallium arsenic (GaAs), indium arsenide (InAs), or indium phosphide (InP), or another suitable compound semiconductor. In some embodiments, the substrate is made of an alloy semiconductor such as gallium arsenide phosphide (GaAsP), aluminum indium arsenide (AlInAs), aluminum gallium arsenic (AlGaAs), gallium indium arsenide (GaInAs), gallium indium phosphide (GaInP), or gallium indium arsenide phosphide (GaInAsP), or another suitable alloy semiconductor.

In the example shown in FIGS. 1A and 1B, the substrate includes layers 101, 102, and 103. In an embodiment, layer 101 is a Si layer, layer 102 is a Si/Ge layer, and layer 103 is a another Si layer. In another embodiment, layer 102 is a dielectric layer, e.g., a silicon oxide layer, forming a silicon-on-oxide (SOI) substrate including layers 103, 102, and 101. In either case, layer 101 may be a top portion of a Si wafer.

As shown in FIGS. 1A and 1B, in this example, intermediate structures 100 and 200 each includes a stack of alternating first semiconductor layers 110 and second semiconductor layers 120. Although 6 layers of 110 and 120 shown to be included in the intermediate structures 100 and 200, this is not intended to be limiting. In some examples, the total number of layers in the 102 or 202 is between three and twenty. For example, there may be six layers or ten layers in each of the intermediate structures 100 and 200. In other embodiments, there can be more or fewer layers. In some examples, the thickness of the stacked semiconductor layers 110 and 120 is in a range from about 5 nm to about 100 nm. In other embodiments, the thickness can be thinner or thicker. Also it should be understood although same number of alternative semiconductor layers 110 and 120 are shown in this example, this is also not intended to be limiting. It is understood that intermediate structure 100 can have different number of alternating semiconductor layers 110 and 120 than intermediate structure 200.

In various embodiments, the semiconductor layers 110 and 120 are made of different semiconductor materials such as silicon, germanium, silicon germanium (SiGe), gallium arsenic (GaAs), indium arsenide (InAs), silicon carbide (SiC), indium gallium arsenide (InGaAs), or other suitable semiconductor materials. In some embodiments, the semiconductor layers 110 are made of SiGe, and the semiconductor layers 120 are made of Si. Semiconductor layer 110 or the semiconductor layer 120 may be formed alternately on the substrate by blanket epitaxial growth processes. Next, the stacked alternating first semiconductor layers 110 and second semiconductor layers 120 on the substrate are patterned using photolithography and etching processes to form two separate stacks of intermediate structures 100 and 200 in device region 1 and device region 2 of the substrate; respectively, device region 1 and device region 2 can be located in different parts of the substrate for an IC chip. In some embodiments, device region 1 and device region 2 can be located in adjacent parts of the substrate to facilitate interconnection.

To form stacks, the semiconductor layers are deposited sequentially, for example, using an epitaxial process (EPI). To pattern the stacks, a patterned mask (not shown) is formed on the stacked semiconductor layers 110 and 120 in the patterning and etching process. The mask can be a photoresist mask or a hard mask. In some examples, the hard mask is made of silicon oxide (SiO₂), silicon carbon nitride (SiCN), silicon oxycarbide (SiOC), silicon oxycarbon nitride (SiOCN) silicon nitride (SiN or Si₃N₄), or another suitable material. The hard mask is formed using deposition, photolithography, and etching processes. The etching processes may include a reactive ion etch (ME), neutral beam etch (NBE), inductive coupled plasma (ICP) etch, or another suitable etch process, or a combination thereof.

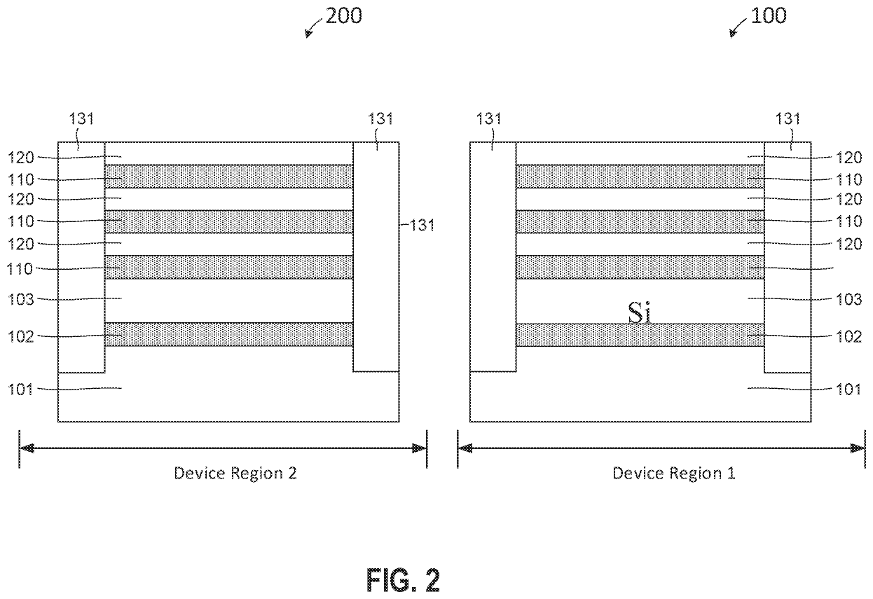

FIGS. 2, 3, 4, 5A, and 5B illustrate cross-sectional views of respective intermediate structures at subsequent stages to that shown FIGS. 1A-B in the example method for fabricating the example memory device in device regions 1 and 2, respectively, in accordance with the disclosure.

As shown in FIG. 2, multiple isolation structures 131 are formed at the sides of the intermediate structures 100 and 200. As shown, in this example, portions of the intermediate structures 100 and 200 are removed to form trenches between adjacent intermediate structures 100 and 200, and an isolation material is deposited in the trenches to form the isolation structures 131 at the sides of the stacked structures. The process of removing portions of the intermediate structures 100 and 200 is similar to the mask and etch processes described above in connection with FIGS. 1A and 1B.

In various embodiments, the isolation structure 131 is a shallow-trench-isolation (STI) structure, which surrounds the remaining the stack structures. In those embodiments, the isolation structure 131 is formed by filling the trenches with an insulating material. The insulating material can be silicon oxide, silicon nitride, silicon oxynitride, fluoride-doped silicate glass (FSG), or another low dielectric constant (low-k) dielectric material. The trenches may be filled with the insulating material using a deposition process, such as chemical vapor deposition (CVD), flowable CVD (FCVD), a spin-on-glass (SOG) process, or another suitable process. The deposition process can be followed by a planarization process, such as a chemical-mechanical polishing (CMP) process or an etching process.

In some embodiments, a liner (not shown) may be formed between the isolation structures 131 and stacked structures. In these embodiments, a liner material layer for forming the liner is conformally deposited on the sidewalls of the stacked structures before filling the trenches with the insulating material. The material of the liner 103 may be silicon oxide, silicon nitride, silicon oxynitride, or another suitable material. The liner material layer may be deposited using CVD, physical vapor deposition (PVD), atomic layer deposition (ALD) process, or another suitable process.

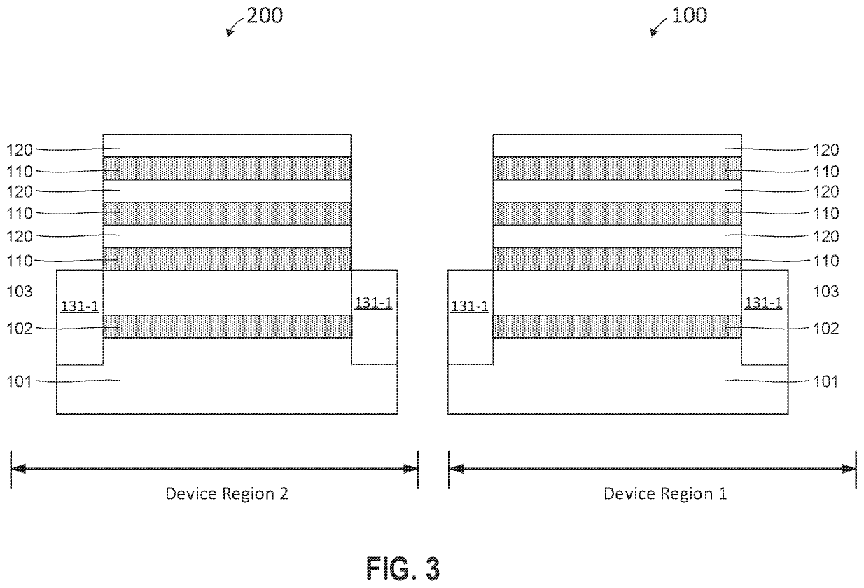

In FIG. 3, in this example, isolation structures 131 are recessed by an etching process to expose the stacks of alternating first semiconductor layers 110 and second semiconductor layers 120. The etching process can include ME, NBE or another suitable etching process. In some instances, the top surfaces of the recessed isolation structures 131-1 are selected to expose suitable numbers of alternating first semiconductor layers 110 and second semiconductor layers 120.

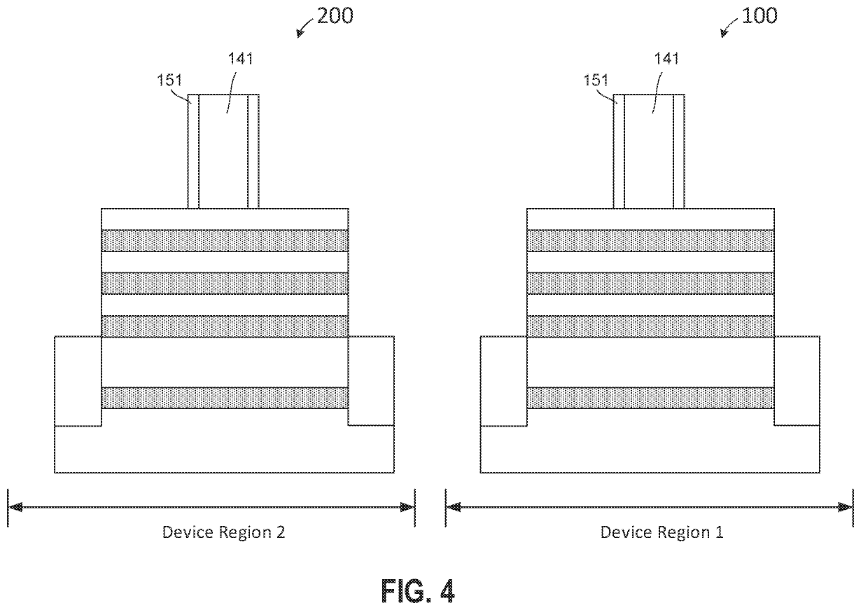

In FIG. 4, dummy gate structures 141 and gate spacers 151 are formed on top of the stacks of alternating first semiconductor layers 110 and second semiconductor layers 120 in device regions 1 and 2, as shown. In some embodiments, each of the dummy gate structures 141 are replaced with a replacement gate structure in subsequent processing steps.

Each of the dummy gate structures 141 can include a dummy gate dielectric layer on the top of the stacked semiconductor layers and a dummy gate electrode layer on the dummy gate dielectric layer. In some embodiments, the dummy gate electrode layer is made of poly-silicon. In some embodiments, the dummy gate dielectric layer made of silicon oxide, silicon nitride, silicon oxynitride, or other low dielectric constant (low-k) dielectric material. The dummy gate dielectric layer and the dummy gate electrode layer are deposited independently, and then may be patterned together using photolithography and etching processes to form the dummy gate structures 141. The deposition processes for the dummy gate dielectric layer and the dummy gate electrode layer may include CVD, PVD, ALD, high density plasma CVD (HDPCVD), metal organic CVD (MOCVD), or plasma enhanced CVD (PECVD) processes. The etching processes for forming the dummy gate structures 141 may include RIE, NBE, or another suitable etching process.

A hard mask layer is formed on the dummy gate electrode layer and patterned to serve as an etching mask for forming the dummy gate structures 141. In some examples, the hard mask is made of silicon oxide (SiO₂), silicon carbon nitride (SiCN), silicon oxycarbide (SiOC), silicon oxycarbon nitride (SiOCN) or silicon nitride (SiN or Si₃N₄). The hard mask [[118]] may be made of silicon oxide (SiO₂). The hard mask may be formed using deposition, photolithography and etching processes.

In this example, the gate spacers 151 is formed by conformally depositing one or more spacer layers (not shown) on the dummy gate structures 141, and along the sidewalls of the dummy gate structures 141. The spacer layers may be made of different materials and have different thicknesses than each other. The one or more spacer layers may include silicon oxide (SiO₂), silicon nitride (e.g. SiN or Si₃N₄), silicon oxynitride (SiON), silicon carbon nitride (SiCN), silicon oxycarbide nitride (SiOCN), silicon oxycarbide (SiOC), or a combination thereof, and may be deposited by CVD, ALD or another deposition process. The spacer layers are then anisotropically etched to form the gate spacers 151. The etching process may include a RIE, NBE, or other etching processes.

Next, starting with the intermediate structures in FIG. 4, using dummy gate structures 141 and gate spacers 151 as etch masks, the stacks of alternating semiconductor layers 110 and 120 are etched to form fin structures 125 and 225 in device region 1 and device region 2, respectively, as shown in FIGS. 5A and 5B.

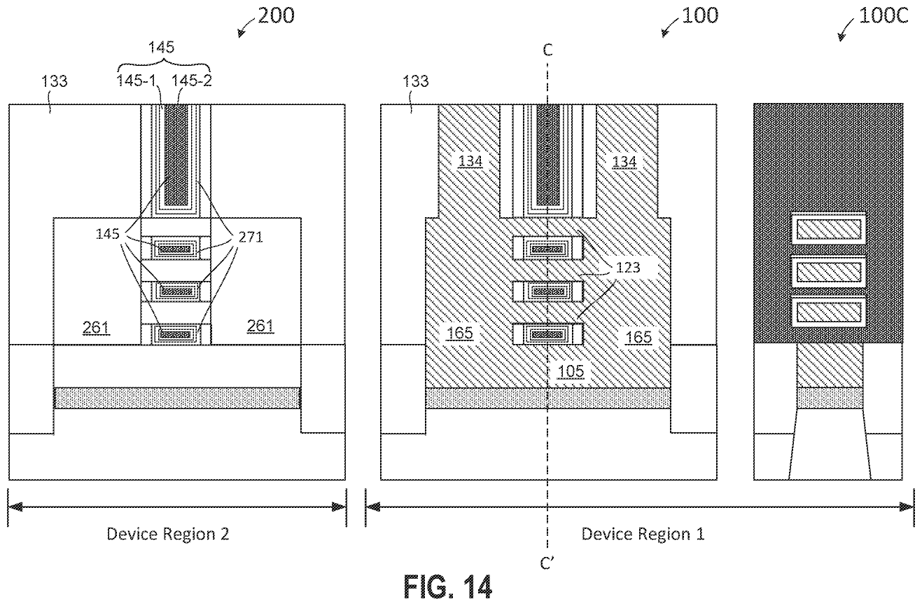

FIGS. 5A and 5B illustrate fin structures are formed in the device regions 1 and 2 in the example method of fabricating the example memory device, in accordance with some embodiments. FIG. 5A illustrates a cross-sectional view, and FIG. 5B illustrates a three-dimensional perspective view of the intermediate structure. The cross-sectional view in FIG. 5A is taken along the A-A′ cutline in FIG. 5B. FIG. 5B also shows a second cutline B-B′ perpendicular to cutline A-A′, which is referred to in subsequent drawings, e.g., in FIGS. 14A, 14B, 15A, 15B, 16A, 16B, 17A, and 17B.

FIGS. 5A and 5B illustrate fin structures 125 and 225. As shown, in this example, each of fin structures 125 and 225 includes a stack of alternating first and second semiconductor strips 112 and 122, respectively. First and second semiconductor strips 112 and 122 are the remaining portions of first and second semiconductor layers 110 and 120 illustrated in FIGS. 1-4. In this example, first and second semiconductor strips 112 and 122 are made of SiGe and Si, respectively. However, this is not intended to be limiting. Other semiconductor materials can also be used; for example, two different semiconductor materials having etch selectivity with respect to each can be used in some embodiments. The etching process may include a ME, NBE, or other etching processes. In some embodiments, a non-selective etching process can be used to etch the SiGe and Si layer concurrently. In other embodiments, selective etching processes can be used to sequentially etch the semiconductor layers.

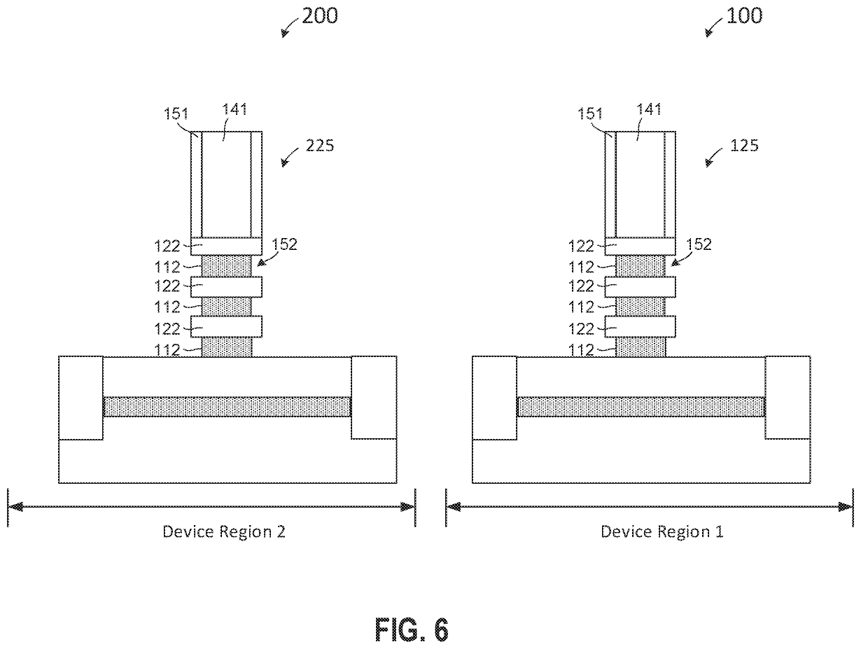

FIGS. 6, 7, 8, 9, 10, 11, 12, and 13 illustrate cross-sectional views of respective intermediate structures at various stages of the example method for fabricating the example memory device in device regions 1 and 2, respectively, in accordance with some embodiments.

In FIG. 6, recessed regions 152 are formed on the sides of first semiconductor strips 112 in fin structures 125 and 225. The semiconductor strips 112 are etched using the dummy gate structure 141 and the gate spacers 151 as etching masks to form recessed regions 152. The recessed regions 152 may be formed using an isotropic etching process such as wet etching, plasma etching, RIE, or another dry etching process. The wet isotropic etching process may use an etching solution such as ammonium hydroxide-peroxide water mixture (APM), tetramethylammonium hydroxide (TMAH), ammonium hydroxide (NH4OH), or another etchant. In embodiments where the first semiconductor strip 112 is made of SiGe and the second semiconductor strip 122 is made of Si, a selective etchant, e.g., TMAH, that etches SiGe at a higher rate than Si can be used.

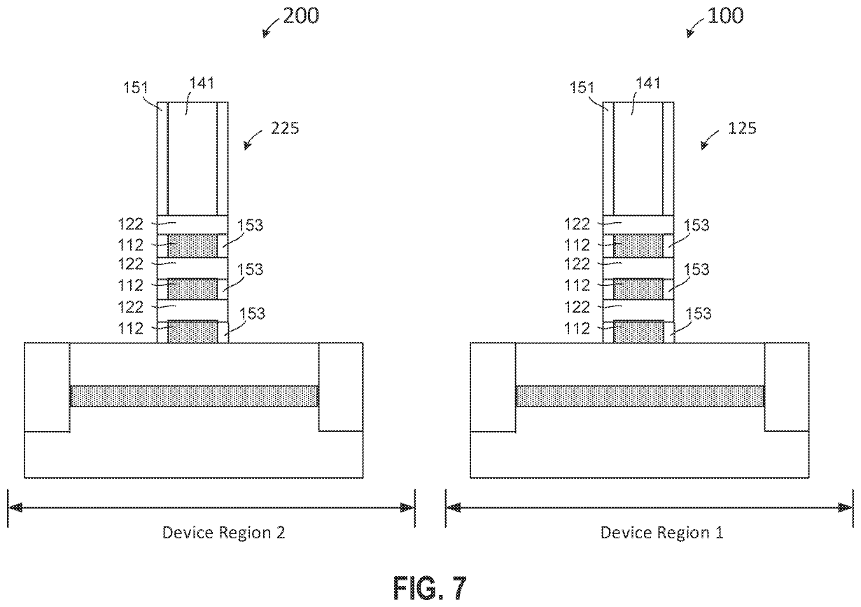

Next, as shown in FIG. 7, inner spacers 153 are formed in the recessed regions 152 on the sides of first semiconductor strips 112. In various embodiments, the inner spacers 153 are formed using a similar process as used in forming the gate spacers 151 described above in connection to FIG. 4. In various embodiments, the inner spacers 153 are formed by conformally depositing one or more spacer layers on the fin structures 125 and 225, and along their sidewalls. The spacer layers may be made of different materials and have different thicknesses than each other. The one or more spacer layers may include silicon oxide (SiO₂), silicon nitride (SiN or Si₃N₄), silicon oxynitride (SiON), silicon carbon nitride (SiCN), silicon oxycarbide nitride (SiOCN), silicon oxycarbide (SiOC), another low-K dielectric, or a combination thereof, and may be deposited by CVD, ALD or another deposition process. The spacer layers are then anisotropically etched to form the inner spacers 153. The etching process may include an RIE, NBE, or other etching processes.

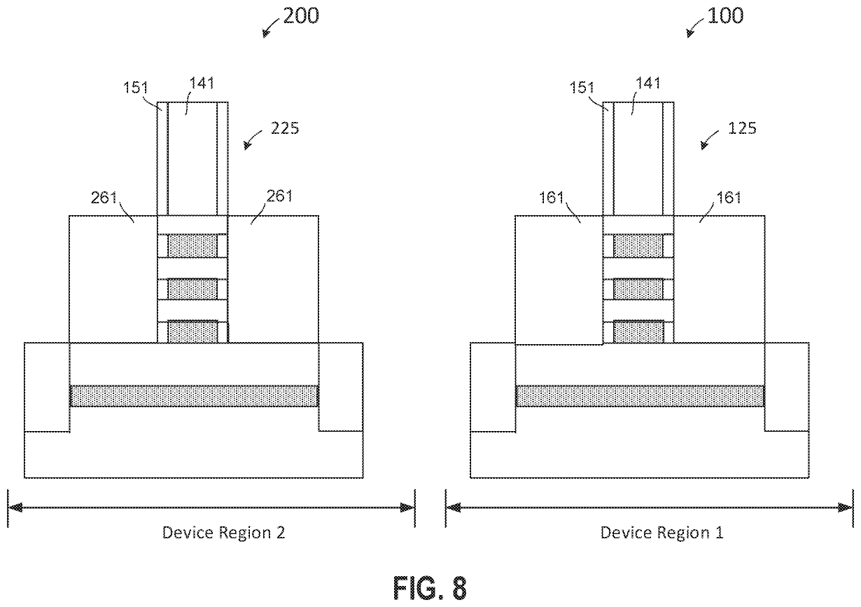

In FIG. 8, semiconductor structures 161 and 261 are formed on the sides of fin structures 125 and 225 in device region 1 and device region 2, respectively. In some instances, the top surfaces of semiconductor structures 161 and 261 may be higher than or at the same level with the top surfaces of the fin structures 125 and 225. The semiconductor structures 161 in the device region 1 and semiconductor structures 261 in the device region 2 may be made of different semiconductor materials formed, for example, by epitaxial processes. The semiconductor materials may include silicon (Si), silicon germanium (SiGe1-x, where x can be between approximately 0 and 1), silicon carbide (SiC), silicon phosphide (SiP), germanium, an III-V compound semiconductor, an II-VI compound semiconductor, or another epitaxial semiconductor. The materials of an III-V compound semiconductor may include InAs, AlAs, GaAs, InP, GaN, InGaAs, InAlAs, GaSb, AlSb, AlP, GaP, or another suitable compound semiconductor.

In some embodiments, semiconductor structures 261 in the device region 2 are used to form source and drain structures of metal-oxide semiconductor field effect transistors (MOSFET), including NMOS transistors or PMOS transistors. In some embodiments, semiconductor structures 261 for NMOS transistors are made of SiC, and semiconductor structures 261 for PMOS transistors are made of SiGe. In some embodiments, semiconductor structures 161 in the device region 1 can be used or replaced to form an electrode for a capacitor or source and drain regions of a transistor, as will be described in detail below.

In various embodiments, the semiconductor structures 161 and the semiconductor structures 261 are independently formed by metal-organic CVD (MOCVD), molecular beam epitaxy (MBE), liquid phase epitaxy (LPE), vapor phase epitaxy (VPE), selective epitaxial growth (SEG), or another suitable process, or a combination thereof. In addition, the semiconductor structures 161 and the semiconductor structures 261 may be independently doped by in-situ doping during the epitaxial growth and/or by implantation after the epitaxial growth. In this case, patterned hard masks are used to protect the regions not receiving deposition or doping.

In some embodiments, semiconductor structures 161 in device region 1 are replaced by a different material. In those embodiments semiconductor structures 161 and 261 can be formed simultaneously to simplify the process.

In this example, the semiconductor structures 161 and 261 are used as source and drain for the example memory device. In some embodiments, the source and drain of the memory devices in accordance with the disclosure, when formed on a wafer, may be shared between two neighboring transistors, such as through coalescing the structures by epitaxial growth. For example, the neighboring memory devices with the shared source and drain structures may be implemented as two functional transistors. Other configurations in other examples may implement other numbers of functional transistors.

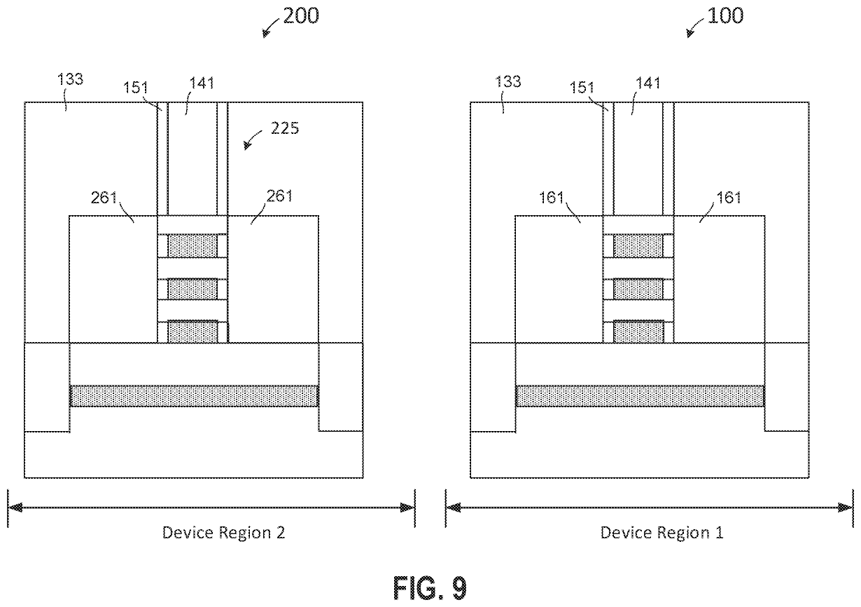

In FIG. 9, an interlayer dielectric (ILD) layer 133 is formed on the sides of the structures in FIG. 8, in accordance with some embodiments. In this process, an interlayer dielectric (ILD) layer 133 is formed on the source and drain structures 122. In some embodiments, a contact etch stop layer (CESL) can be deposited before the deposition of the ILD layer 133. The ILD layer 133 is then deposited on the CESL, which is not shown to simplify the drawing. The CESL can provide a mechanism to stop an etching process when forming contacts to the semiconductor layers. The CESL may be formed of a dielectric material having a different etch selectivity from the adjacent ILD layer 144. The material of the CESL may include silicon nitride (SiN or Si3N4), silicon carbon nitride (SiCN), or a combination thereof, and may be deposited by CVD, PECVD, ALD, or another deposition process. The material of the ILD layer 133 may include silicon dioxide (SiO2) or a low-k dielectric material (e.g., a material having a dielectric constant (k-value) lower than the k-value (about 3.9) of silicon dioxide). The low-k dielectric material may include silicon oxynitride (SiON), phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG), another low-k dielectric material, or a combination thereof. The ILD layer 133 may be deposited by spin-on coating, CVD, Flowable CVD (FCVD), PECVD, PVD, or another deposition process.

After the deposition of the ILD layer 133, a planarization process, for example a chemical mechanical polishing (CMP) process, is performed on the ILD layer 133 and the CESL. After the planarization process, the dummy gate structure 141 are exposed. The top surfaces of the ILD layer 133 and the CESL may be coplanar with the top surfaces of the dummy gate electrode layers 141 and the gate spacers 151, as shown in FIG. 9.

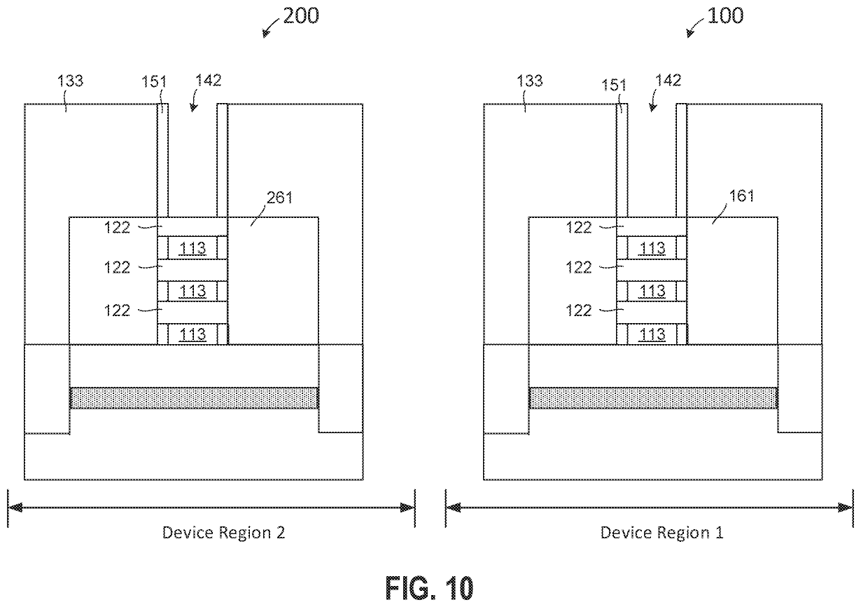

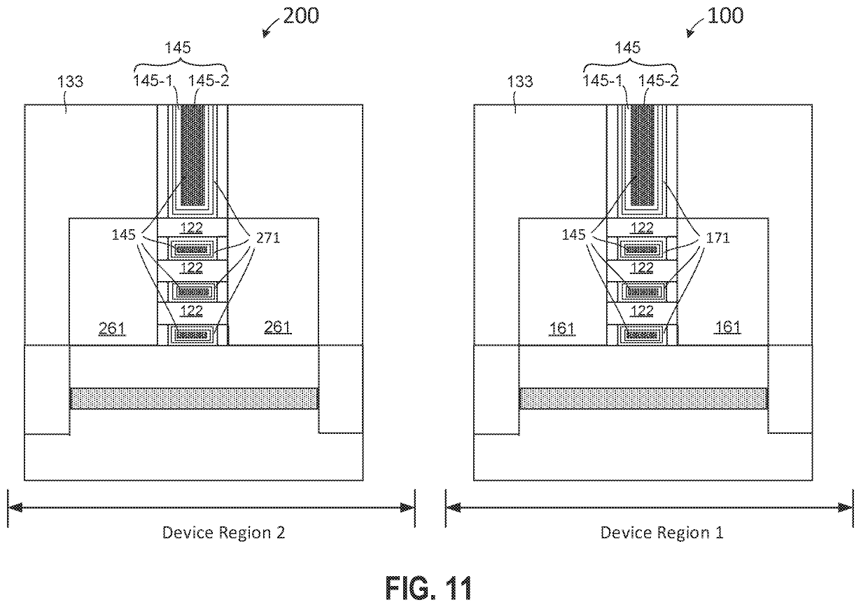

In FIG. 10, the dummy gate structure 141 and the first semiconductor strips 112 are removed, in accordance with some embodiments. The dummy gate structure 141 and the first semiconductor strips 112 in FIG. 9 can be removed using one or more etching processes. Removing the dummy gate structure 141 leaves a void 142 in its place, and removing the first semiconductor strips 112 in FIG. 9 forms first voids 113 between adjacent second semiconductor strips 122, in both the first and the second stacked structures 125 and 225. In some embodiments, each of the first voids 113 can have a height in a range from about 3 nm to about 15 nm. The semiconductor strips 122 are stacked and separated from each other by a distance that is in a range from about 3 nm to about 15 nm. Each of the semiconductor strips 122 can have a thickness in a range from about 3 nm to about 15 nm. However, it is understood that the thickness and spacing ranges are only cited as examples, and variations can be made depending on the applications. The stacked semiconductor strips 122 may also be referred to as nanostructures, nanosheets, or nanowires. As described below, semiconductor strips 122 can serve as channel layers of transistors formed subsequently.

Depending on the material compositions of the dummy gate structure 141 and the first semiconductor strips 112, appropriate etching processes can be used. For example, in some embodiments, the dummy gate structure 141 includes polysilicon as the dummy electrode material, and the etching of the dummy gate structure can be carried out using known dry or wet polysilicon etching processes. In the embodiments where semiconductor strips 112 are made of Si and semiconductor strips 122 are made of SiGe. The etching of first semiconductor strips 112 can include using a dry etching process or a wet etching process with a higher etching rate of Si than SiGe. For example, the wet etching process can include using a mixture of sulfuric acid (H₂SO₄) and hydrogen peroxide (H₂O₂) (SPM) and/or a mixture of ammonia hydroxide (NH₄OH) with H₂O₂ and deionized (DI) water (APM), or another suitable etchant. As a result of the etching of first semiconductor strips 112, suspended regions of second semiconductor strips 122 can be formed with first voids 113 between them.

In FIG. 11, a first dielectric structure layer 171 and a second dielectric structure layer 271 are deposited to surround the second semiconductor strips 122 in the first and second device regions, respectively. Next, a first conductive fill material 145 is deposited to surround the first dielectric structure layer and the second dielectric structure layer, respectively.

In device region 1, the first dielectric structure layer 171 is formed in the first voids 113, shown in FIG. 10, between the second semiconductor strips 122 and the void 142 vacated by the dummy gate structure 141. As a result, the first dielectric structure layer 171 is formed surrounding the second semiconductor strips 122. The first dielectric structure layer 171 can include an interfacial layer (IL). As an example, the interfacial oxide layer can be formed by exposing the second semiconductor strips 122 and gate spacers 151 to an oxidizing ambient. The oxidizing ambient can include a combination of ozone (O₃), a mixture of ammonia hydroxide (NH₃OH), hydrogen peroxide (H₂O₂), and water, also known as the SC1 solution, and/or a mixture of hydrochloric acid (HCl), hydrogen peroxide, (H₂O₂), and water, also known as the SC2 solution, or another suitable oxidizing ambient. As a result of the oxidation process, oxide layers ranging from about 0.5 nm to about 1.5 nm, also referred to as chemical oxide or native oxide, can be formed on the exposed surfaces of the second semiconductor strips 122. However, it is understood that the thickness range is only cited as examples, and variations can be made depending on the applications.

The first dielectric structure layer 171 may also include a high-k gate dielectric layer (HK), which can be substantially conformally deposited on the interfacial oxide layers. In some embodiments, the gate dielectric layer can include a dielectric material with a dielectric constant (k-value) higher than about 3.9. In some embodiments, the gate dielectric layer can include (i) silicon oxide, silicon nitride, and/or silicon oxynitride, or another suitable dielectric material, (ii) a high-k dielectric material, including ferroelectric materials, such as hafnium oxide (HfO₂), TiO₂, HfZrO, Ta₂O₃, HfSiO₄, ZrO₂, ZrSiO₂, or another suitable ferroelectric material, (iii) a high-k dielectric material having oxides of Li, Be, Mg, Ca, Sr, Sc, Y, Zr, Al, La, Ce, Pr, Nd, Sm, Eu, Gd, Tb, Dy, Ho, Er, Tm, Yb, or Lu, or another suitable high-k dielectric material, or (iv) a combination thereof. The interfacial layer and the gate dielectric layer (e.g., HfZrO or HfO₂) can each be formed by ALD and/or other suitable methods. In some embodiments, the gate dielectric layer can be formed with ALD using hafnium chloride (HfCl₄) as a precursor at a temperature ranging from about 250° C. to about 350° C. However, it is understood that the temperature range is only cited as examples, and variations can be made depending on the applications. In some embodiments, the first dielectric structure layer 171 can have a thickness ranging from about 1 nm to about 3 nm in order to wrap around the second semiconductor strips 122 without being constrained by spacing between adjacent the second semiconductor strips 122. However, it is understood that the thickness range are only cited as examples, and variations can be made depending on the applications.

Similarly, in device region 2, the second dielectric structure layer 271 are formed in the first voids 113 between the second semiconductor strips 122 and the void 142 vacated by the dummy gate structure 141. As a result, the second dielectric structure layer 271 is formed surrounding the second semiconductor strips 122. The second dielectric structure layer 271 can include an interfacial layer (IL). As an example, the interfacial oxide layer can be formed by exposing the second semiconductor strips 122 and gate spacers 141 to an oxidizing ambient. The oxidizing ambient can include a combination of ozone (03), a mixture of ammonia hydroxide (NH₃OH), hydrogen peroxide (H₂O₂), and water, also known as the SC1 solution, and/or a mixture of hydrochloric acid (HCl), hydrogen peroxide, (H₂O₂), and water, also known as the SC2 solution. As a result of the oxidation process, oxide layers ranging from about 0.5 nm to about 1.5 nm, also referred to as chemical oxide or native oxide, can be formed on the exposed surfaces of the second semiconductor strips 122. However, it is understood that the thickness range is only cited as examples, and variations can be made depending on the applications.

The second dielectric structure layer 271 may also include a high-k gate dielectric layer (HK), which can be substantially conformally deposited on the interfacial layers. In some embodiments, the gate dielectric layer can include a dielectric material with a dielectric constant (k-value) higher than about 3.9. In some embodiments, the gate dielectric layer can include (i) silicon oxide, silicon nitride, and/or silicon oxynitride, or another suitable dielectric material, (ii) a high-k dielectric material, including ferroelectric materials, such as hafnium oxide (HfO₂), TiO₂, HfZrO, Ta₂O₃, HfSiO₄, ZrO₂, ZrSiO₂, or another suitable ferroelectric material, (iii) a high-k dielectric material having oxides of Li, Be, Mg, Ca, Sr, Sc, Y, Zr, Al, La, Ce, Pr, Nd, Sm, Eu, Gd, Tb, Dy, Ho, Er, Tm, Yb, or Lu, or another suitable high-k dielectric material, or (iv) a combination thereof. The interfacial layer and the gate dielectric layer (e.g., HfZrO or HfO₂) can each be formed by ALD and/or other suitable methods. In some embodiments, the gate dielectric layer can be formed with ALD using hafnium chloride (HfCl₄) as a precursor at a temperature ranging from about 250° C. to about 350° C. However, it is understood that the temperature range is only cited as examples, and variations can be made depending on the applications. In some embodiments, the second dielectric structure layer 271 can have a thickness ranging from about 1 nm to about 3 nm in order to wrap around the second semiconductor strips 122 without being constrained by spacing between the second semiconductor strips 122. However, it is understood that the thickness ranges are only cited as examples, and variations can be made depending on the applications.

In some embodiments, the first dielectric structure layer 171 includes high-k dielectric layer HfZrO for increased charge storage when a capacitor or memory device is formed in device region 1, and the second dielectric structure layer 271 includes high-k dielectric layer HfO2 when a FET device is formed in device region 2.

In some embodiments, during device fabrication, the etching of the dielectric structure layers and metal layers can be performed using atomic layer etching (ALE) with a control process based on artificial intelligence (A.I.) or machine learning.

Referring back to FIG. 11, the first dielectric structure layer 171 and the second dielectric structure layer 271 are deposited to surround the second semiconductor strips 122 in the device regions 1 and 2, respectively, and on gate spacers 141 and 151. When different dielectric structure layers are desirable in device regions 1 and 2, a patterned hard mask can be used to protect the device region not receiving the deposition.

Next, a first conductive fill material 145 is formed over the first dielectric structure layer 171 and the second dielectric structure layer 271 to surround the second semiconductor strips 122 in device regions 1 and 2, respectively and to fill the voids 142. In some embodiments, the first conductive fill material 145 includes an adhesion/barrier layer 145-1 and a metal fill material 145-2. For example, the adhesion/barrier layer 145-1 can include a titanium nitride (TiN) layer, and the metal fill material 145-2 can include a tungsten (W) material. The adhesion/barrier layer 145-1 can improve the adhesion between the metal fill material and the dielectric structure layer and prevent diffusion of elements (e.g., metals and oxygen) into dielectric structure layers. In some embodiments, the titanium nitride (TiN) layer can be replaced with other suitable materials, such as TaN, TiN, TaAlN, TiAlN, TaSiN, TiSiN, or AlN, etc. Similarly, the tungsten (W) material can be replaced by other conductive materials, such as cobalt (Co). The formation of adhesion/barrier layer 145-1 and metal fill material 145-2 can be made by known processes, such as ALD, CVD, etc., or another suitable process.

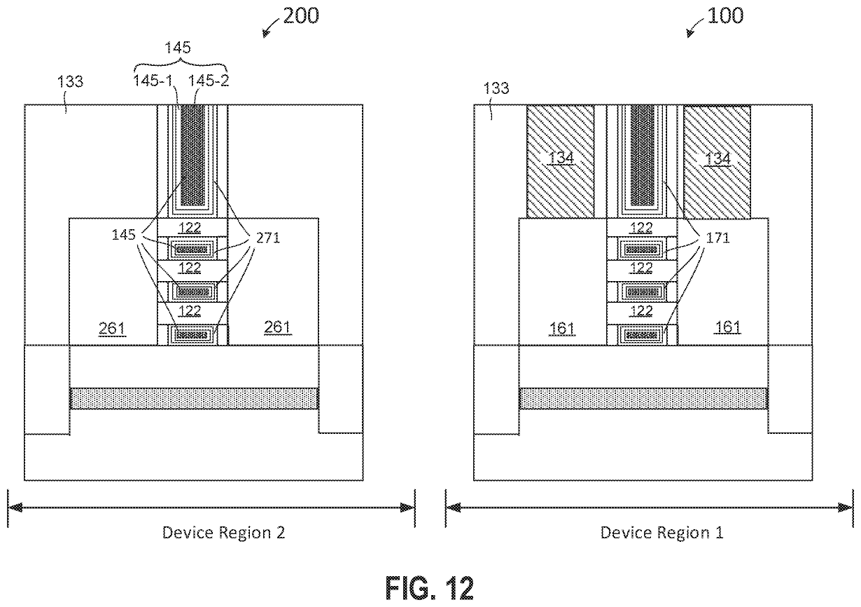

As shown in FIG. 11, in device region 2, the first conductive fill material 145 is configured to form a gate electrode for a gate-all-around (GAA) transistor, with dielectric structure 271 as the gate dielectric, and semiconductor structures 261 as the source and drain regions. In this example, the structure in device regions 1 and 2 form the example memory device in the form of FeRAM. The process of forming the example memory device in device regions 1 and 2 is continued to be illustrated below with reference to FIGS. 12, 13, 14A, 14B, 15A, and 15B. In some embodiments, the structure in device region 2 can be protected with a mask, such as a patterned photo resist layer or hard mask.

In FIG. 12, as shown, voids 134 are formed in the ILD layer 133 in the first device region. The voids 134 can be formed by etching the ILD layer using a known etching process with a patterned mask. The void 134 exposes semiconductor region 161.

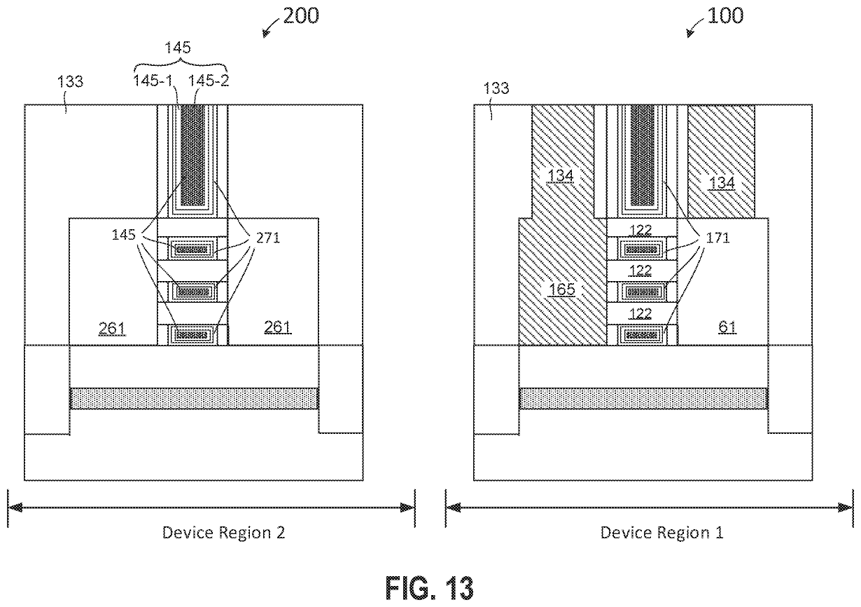

In FIG. 13, at least a portion of semiconductor structure 161 in the first device region is removed to form a void 165 and expose the second semiconductor strips 122. In embodiments where the semiconductor structure 161 is made of SiGe and the second semiconductor strip 122 is made of Si, selective etchant, e.g., TMAH, that etches SiGe at a higher rate than Si can be used to remove a portion or all of semiconductor regions 161.

FIGS. 14-17 illustrate cross-sectional views of respective intermediate structures at various stages of the example method for fabricating the example memory device in device regions 1 and 2, in accordance with some embodiments.

In FIG. 14, as shown, the second semiconductor strips 122 in the first device region are removed to form second voids 123. As used herein, the second voids refer to the stacked void regions formed by removing stacked semiconductor strips 122, in contrast to first voids 113, which were formed by removing stacked semiconductor strips 112. Further, the semiconductor layer 103, as shown in FIG. 1A, is also removed to form a void 105. In device region 1, interconnected voids are formed, including voids 134, 165, 123, and 105. In embodiments where the second semiconductor strip 122 is made of Si, an isotropic Si etchant can be used to remove the second semiconductor strips 122. The right portion of FIG. 14 also shows a cross-sectional view 100C of the intermediate device structure 100 in device region 1 along a cutline C-C′ shown in device region 1, which defines a plane perpendicular to the drawing sheet, similar to the plane defined by the cutline B-B′ in FIG. 5B. The lateral dimension of the C-C′ cross-sectional view 100C is shortened to fit in the figure.

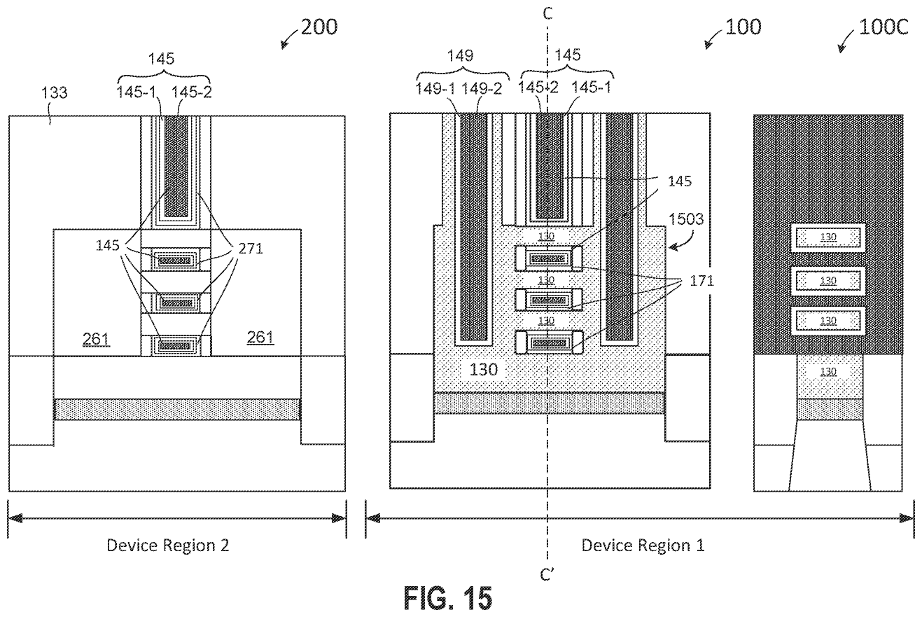

FIG. 15 illustrates a cross-sectional view of an intermediate structure for a GAA FeRAM cell, in accordance with some embodiments. Starting with the device structures in FIG. 14, the structure in the device region 1 includes second voids 123 between portions of the first dielectric structure layer 171. As described above in connection with FIGS. 1-14, the first dielectric structures 171 are formed in first voids 113 created by removing the first semiconductor strips 112, which are made of a first semiconductor material. Moreover, the second voids 123 are created by removing the second semiconductor strips 122, which are made of a second semiconductor material. The structure in the device region 1 also includes voids 134 formed in the ILD layer 133, and void 165 formed in the semiconductor structure 161. In FIG. 15, a third semiconductor material 1502 is deposited in the interconnected voids formed by the second voids 123 between portions of the first dielectric structure layer 171, the voids 134 formed in the ILD layer 133, and the void 165 formed in the semiconductor structure 161. In some embodiments, the first semiconductor material is SiGe, the second semiconductor material is Si, and the third semiconductor material 1502 is indium gallium zinc oxide (IGZO). The right portion of FIG. 15 also shows a cross-sectional view 100C of device 100 along a cutline C-C′ shown device region 1, which defines a plane perpendicular to the drawing sheet. The lateral dimension of the C-C′ cross-sectional view 100C is shortened to fit in the figure.

IGZO is a metal-oxide semiconducting material, formed by indium (In), gallium (Ga), zinc (Zn) and oxygen (O). IGZO is an amorphous semiconductor material, which has 20-50 times the electron mobility of amorphous silicon. It can be deposited as a uniform amorphous phase while retaining the high carrier mobility. Using other semiconductor materials, it would be difficult to form single crystalline epitaxial semiconductor materials in the interconnected voids described above. Therefore, IGZO is suitable as a filling material to fill in the interconnected voids to form the integral semiconductor structure 1503 in FIG. 15B. IGZO is a metal-oxide semiconductor and can avoid low-k interfacial layer with high-k ferroelectric HfO2 gate insulator. Moreover, IGZO is an N-type semiconductor and can be used in junctionless transistor operation, and avoid charge trapping, which occurs in inversion mode operation.

IGZO can be manufactured using a synthesis method, for example, a low temperature atomic layer deposition (ALD) process, for example, at or below 250° C. In some embodiments, IGZO can be manufactured using solution processing, such as a pulsed laser deposition (PLD), or spin coating, which involves depositing In and Ga solution layers onto a hot plate and annealing at temperatures roughly between 200° C. and 400° C., depending on the target composition. Subsequently, the films can be annealed in air.

Next, a third conductive fill material 149 is deposited in the spaces in second voids 123 and 165 that are not filled by the third semiconductor material 1502. In some embodiments, the third semiconductor material 130 is etched to form the spaces. In some embodiments, the third conductive fill material 149 can be similar to conductive fill materials 145 and 147 described above. The third conductive fill material 149 includes an adhesion/barrier layer 149-1 and a metal fill material 149-2. For example, the adhesion/barrier layer 149-1 can include a titanium nitride (TiN) layer, and the metal fill material 149-2 can include a tungsten (W) material. The adhesion/barrier layer 149-1 can improve the adhesion between the metal fill material and the dielectric structure layer and prevent diffusion of elements (e.g., metals and oxygen) dielectric structure layers. The formation of adhesion/barrier layer 149-1 and metal fill material 149-2 can be made by known processes, such as ALD, CVD, etc.

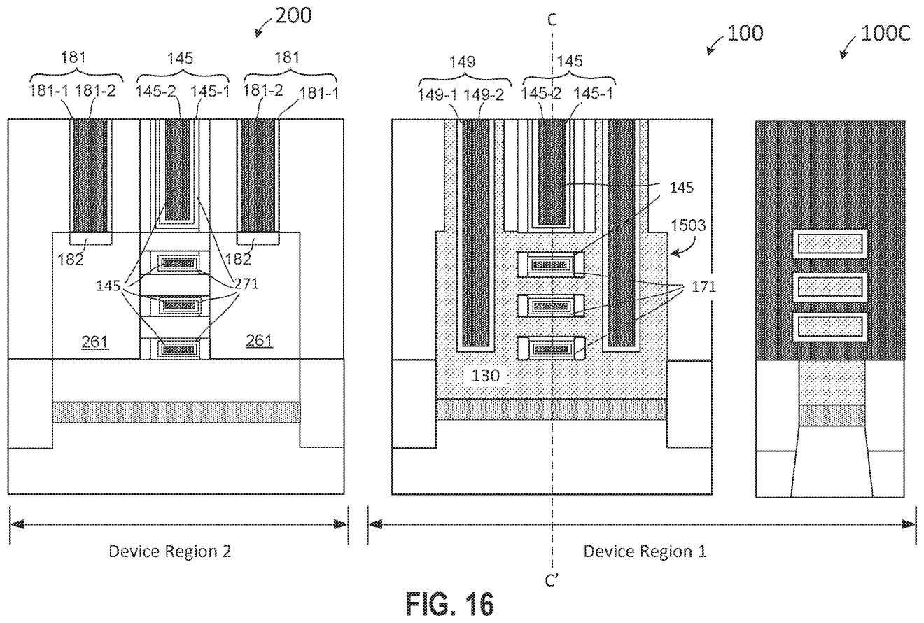

FIG. 16 illustrates the same device structures as shown in FIG. 15, with the additional feature of metal contact structures 181 for source and drain regions for the transistor device in device region 2, in accordance with some embodiments. In FIG. 16, metal contact structures 181 are formed in contact holes etched in the dielectric layer. In some embodiments, metal contact structure 181 includes an adhesion/barrier layer 181-1 and a metal fill material 181-2. For example, the adhesion/barrier layer 181-1 can include a titanium nitride (TiN) layer, and the metal fill material 181-2 can include a tungsten (W) material. The adhesion/barrier layer 181-1 can improve the adhesion between the metal fill material and the dielectric structure layer and prevent diffusion of elements (e.g., metals and oxygen) dielectric structure layers. The formation of adhesion/barrier layer 181-1 and metal fill material 181-2 can be made by known processes, such as ALD, CVD, etc. In some embodiments, metal contact structure 181 can also include a silicide layer 182 formed at the bottom of the contact hole to improve the adhesion and reduce contact resistance between the metal contact structure and the underlying semiconductor surface. The right portion of FIG. 16 shows cross-sectional views 100C of device 100 along a cutline C-C′ shown device region 1, which defines a plane perpendicular to the drawing sheet. The lateral dimension of the C-C′ cross-sectional view 100C is shortened to fit in the figure.

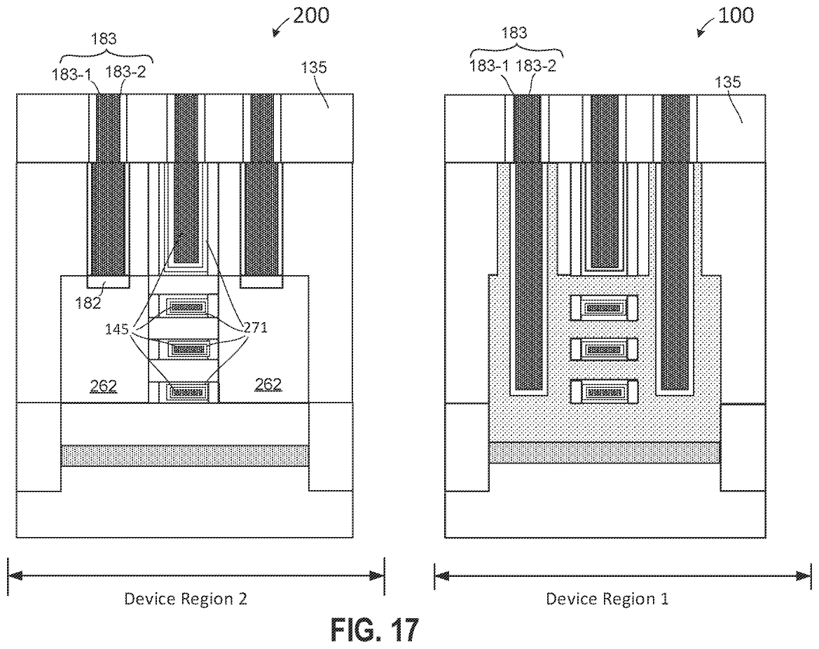

FIG. 17 illustrates the same device structures as shown in FIG. 16 with the addition of via structures 183 for source and drain regions for the transistor device in device region 2 and for electrodes in the memory device in device region 1, in accordance with some embodiments. In FIG. 17, via structures 183 are formed as vias etched in a dielectric layer 135 formed over the device structures in FIG. 16. In some embodiments, the via structure 183 includes an adhesion/barrier layer 183-1 and a metal fill material 183-2. For example, the adhesion/barrier layer 183-1 can include a titanium nitride (TiN) layer, and the metal fill material 183-2 can include a tungsten (W) material. The adhesion/barrier layer 183-1 can improve the adhesion between the metal fill material and the dielectric structure layer and prevent diffusion of elements (e.g., metals and oxygen) in dielectric structure layers. The formation of adhesion/barrier layer 183-1 and metal fill material 183-2 can be made by known processes, such as ALD, CVD, etc., or another suitable process.

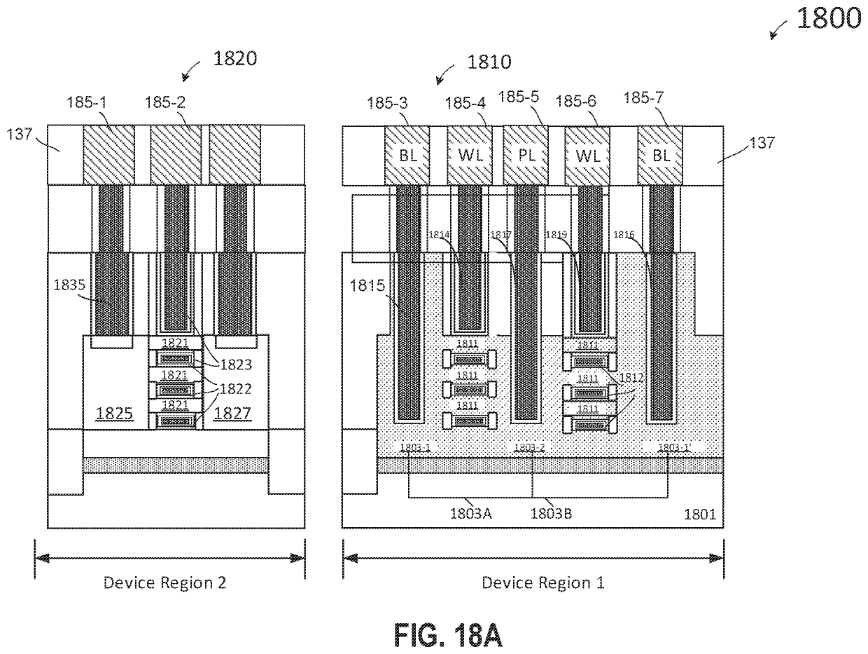

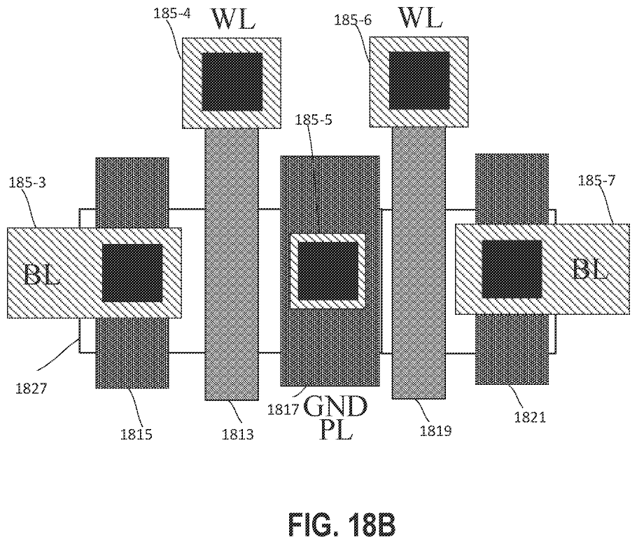

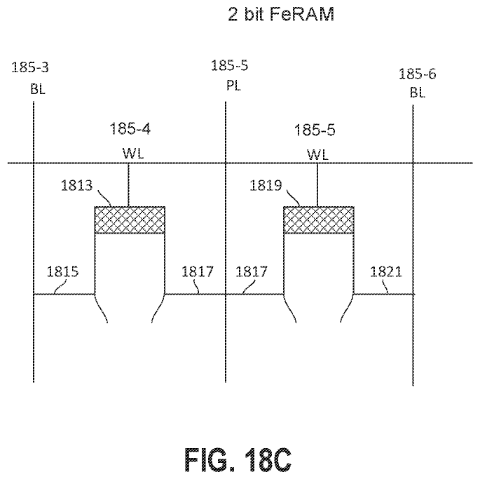

FIGS. 18A-C illustrate a cross-sectional view, a top view and a schematic diagram of a memory device having a ferroelectric memory element in accordance with some embodiments. In various implementations, the memory device is formed using the example fabrication processing shown in FIGS. 2-17. As shown, the memory device includes a transistor 1820 formed in device region 1 and a FeRAM device 1810 formed in device region 2. In various embodiments, transistor 1820 is referred to as an active device, and FeRAM device 1810 is referred to as a passive device.

In FIG. 18A, as shown, metal structures 185 are formed in device regions 2 and 1, respectively. In this example, metal interconnect structures 185 are formed in a dielectric layer 137 over the device structures shown in FIG. 17. However, this is not necessarily the only case. In some embodiments, metal interconnect structures 185 can be formed by etching trenches in dielectric layer 137, followed by electro-copper plating (ECP) to fill the trenches with copper (Cu), and copper chemical-mechanical-polishing (CMP) for planarization.

In FIG. 18A, as shown, memory device 1810 includes stacked conductive electrode strips 1811 disposed in device region 1 on the substrate 1801. As shown, the stacked conductive electrode strips 1811 are separated from one another. In some embodiments, the stacked conductive electrode strips 1811 can be made of titanium nitride (TiN). In alternative embodiments, other suitable material such as T, Ta, TaN, etc., can also be used. In some embodiments, the substrate 1801 can include SOI wafer or SiGe EPI wafer as an etching stop layer. In some embodiments, the SiGe EPI wafer may be doped with boron.

In FIG. 18A, as shown, device 1820 includes stacked semiconductor strips 1821 disposed in device region 2 on the substrate 1801. As can be seen, the semiconductor strips 1821 are separated from one another. As also can be seen, a second dielectric structure layer 1822 is wrapped around the stacked semiconductor strips 1821, and a conductive electrode layer 1823 is wrapped around the second dielectric structure layer 1822 and the semiconductor strips 1821. In some embodiments, the stacked semiconductor strips 1821 can be made of Si or SiGe. In some embodiments, other suitable semiconductor materials as described above can also be used.

As shown in FIG. 18A, memory device 1810, in a gate-all-around (GAA) structure, may be configured to form a capacitor as a charge storage memory device or a GAA transistor memory storage and access device. The stacked first conductive strips 1811 and the conductive electrodes 1814, 1815, 1817, 1819, and 1816 may be configured as the electrodes of GAA capacitor 1810. Device 1820, including the stacked semiconductor strips 1821, the second dielectric structure layer 1822, and the conductive electrode 1823, in a gate-all-around (GAA) structure, is configured to form a GAA transistor. The stacked semiconductor strips 1821 are configured to form channels of transistor 1820. In some embodiments, the first dielectric structure layer 1821 includes hafnium zirconium oxide (HfZrO), and the second dielectric structure layer 1822 includes hafnium oxide (HfO₂).

In this example, as can be seen, metal interconnect structures 185 are formed to include 185-1 and 185-8 respectively coupled to the drain 1825 and source of transistor 1820. 185-2 coupled to the gate 1823 of transistor 1820, and an interconnect line 185-3 connecting the source 1827 of the transistor 1820.

At device region 2, metal interconnect structures 185 may include, a bit line 185-3, a word line 185-4, a plate line 185-4, another word line 185-6 and another bit line 185-7. In this example, memory device 1810 is a 2 bit FeRAM cell. As shown, FeRAM cell 1810 includes an integral semiconductor structure 1803A having interconnected parts made of the same semiconductor material in a first device region (Device Region 1) of a substrate 1801. The integral semiconductor structure 1803A includes first and second portions, 1803-1 and 1803-2, respectively, connected by stacked strips 1811 of the semiconductor material. The stacked strips are separated from one another. As shown in FIG. 18A, the integral semiconductor structure 1803A is made of interconnected parts, including first and second portions, 1803-1 and 1803-2, respectively, connected by stacked strips 1811 of the semiconductor material. In some embodiments, the integral semiconductor structure 1803 is formed by filling a semiconductor material in interconnected voids created by an etching process, as described above in connection with FIG. 15-17. In some embodiments, the filling semiconductor material is indium gallium zinc oxide (IGZO). In alternative embodiments, other suitable metal-oxide semiconductor materials, such as In₂O₃, ZnO, SnO₂, Cu₂O and CuMO₂ (M=Al, Ga, or In), etc., can also be used. As also shown, the FeRAM cell 1810, in this example, includes a semiconductor structure 1803B comprising the portion 1803-2 and a portion 1803-1′. Semiconductor structure 1803B is the same or substantially similar to semiconductor structure 1803A.

In this example, the first and second portions, 1803-1 and 1803-2, of the integral semiconductor structure 1803A are configured as drain and source of the transistor, respectively, connected by stacked strips 1811 of the semiconductor material, which is configured as the channel regions. The first dielectric structure layer can include the ferroelectric material hafnium zirconium oxide (HfZrO). In other example, other ferroelectric materials can also be used, such as hafnium oxide (HfO₂), etc. Similarly, the 1803-2 and 1803-3 of the semiconductor structure 1803B are configured as source and drain, respectively, also connected by stacked strips 1811.

As mentioned, in this example, memory device 1810 in FIG. 18A is a ferroelectric FET (FeFET) with ferroelectric materials HfZrO or HfO2 as gate dielectric and IGZO channel forming the 2 bit FeRAM cell. This type of FET can provide better subthreshold swing (SS) and higher mobility than poly-silicon channel. The FeFET as a memory device can have the advantages of low-power, high-speed, and high-capacity. Further, ferroelectric-HfZrO and HfO₂ are compatible with CMOS processing.

As can be seen, FeRAM cell 1810 has metal interconnect structures 185 including a bit line (BL) 185-3 coupled to a drain electrode 1815 of the device 1810, a word line (WL) 185-4 coupled to the gate electrode 1813 of the device 1810, and a plate line (PL, or ground line) 185-5 coupled to a source electrode 1817 of the device 1810, another word line 185-6 coupled to gate electrode 1819 and another bit line 185-7 coupled to a drain electrode 1821 of device 1810. As can be seen, the device 1810 in this example thus is a 2 bit FeRAM cell having one common PL. It should be understood although, FIGS. 1-17 illustrate a one bit FeRAM cell is formed in device region 1, the process of making the 2 bit FeRAM cell shown in FIG. 18 is similar that shown in FIGS. 1-17, except that additional semiconductor structures, word line 185-6, and bit line 185-7 are formed similar to corresponding semiconductor structures, word line 185-4 and bit line 185-3. As mentioned above, the 2 bit FeRAM cell shown in FIG. 18A improves device density since has a common PL 185-5.

The advantageous aspects of the embodiment illustrated in FIG. 18A include that the two memory structures of semiconductor structures 1803A and 1803B share a common source (or drain) which is electrically connected to metal structure 185-5. As a result of the shared common source (or drain) the layout area density of the memory device 1810 is greatly improved. For example, because of the shared common source (or drain) the ratio [(G1+G2)/S] of the lengths of the active gate area (G1+G2) to the length of the shared common source (or drain) (S) in the cross-sectional view of FIG. 18A is greatly increased.

For example, in some embodiments, length G1 equals length G2, and is equal to about 8 nm, about 9 nm, about 10 nm, about 12 nm, about 14 nm, about 15 nm, about 16 nm, about 18 nm, about 20 nm, or greater, where the extents of lengths G1 and G2 are defined by the outer boundaries of the inner spacers 153. Furthermore, in some embodiments, length S is equal to about 12 nm, about 13 nm, about 14 nm, about 15 nm, about 16 nm, about 17 nm, about 18 nm, about 19 nm, about 20 nm, about 21 nm, about 22 nm, about 23 nm, or less than about 12 nm, where the extents of length S are defined by the outer boundaries of the inner spacers 153 adjacent to the common source (or drain). Accordingly, the ratio [(G1+G2)/S] may be within a range of about 0.7 to 3.3. In some embodiments, the ratio is with a range of about 1 to 2.5, about 1.5 to 2.5, or about 1.75 to 2. In some embodiments, the ratio [(G1+G2)/S] is greater than about 0.7, about 0.9, about 1, about 1.1, about 1.2, about 1.3, about 1.4, about 1.5, about 1.6, about 1.7, about 1.8, about 1.9, about 2.0, about 2.1, about 2.2, about 2.3, about 2.4, about 2.5, about 2.6, about 2.7, about 2.8, about 2.9, about 3.0, about 3.1, about 3.2, about 3.3 or greater.

In some embodiments, the effective width W of the memory structures 2210 and 2220 is about 30 nm, about 35 nm, about 40 nm, about 45 nm, about 50 nm, about 55 nm, about 60 nm, about 65 nm, about 70 nm, about 75 nm, or greater. Accordingly, a ratio W/S may be greater than about 1, about 1.5, about 2, about 2.5, about 3, about 3.5, about 4, about 4.5, about 5, about 5.5, about 6, or about 6.5.

FIG. 18B illustrates a top view layout diagram of the FeRAM cell 1810 shown in FIG. 18A. In implementation, the layout diagram shown in FIG. 18B can be used as a layout for a 2-bit unit cell in an array of FeRAM. 18C illustrates a schematic diagram of the FeRAM cell 1810 shown in FIG. 18A.

Referring back to FIG. 18A, device 1820 is a gate-all-around (GAA) transistor. Device 1820 includes stacked semiconductor strips 1821 disposed in a second device region (Device Region 2) of the substrate 1801, and the semiconductor strips 1821 are separated from one another. A second dielectric structure layer 1822 is wrapped around the stacked semiconductor strips 1821, and a conductive electrode layer 1823 is wrapped around the second dielectric structure layer 1822 and the semiconductor strips 1821. In some embodiments, the stacked semiconductor strips 1821 can be made of Si or SiGe. In alternative embodiments, other suitable semiconductor materials as described above can also be used. In some embodiments, the first dielectric structure layer 1812 includes hafnium zirconium oxide (HfZrO), and the second dielectric structure layer 1822 includes hafnium oxide (HfO₂).

In the example of FIG. 18A, the memory device is an integrated device including an active device 1820, which is a GAA transistor structure that can be used in core/IO/SRAM regions, and multibit FeRAM cell 1810. Both FeRAM cell 1810 and transistor 1820 have a 3D GAA structure, such that the charge storage in the memory and the current drive in the transistor can be increased. Moreover, memory device 1810 has an IGZO channel. IGZO can be manufactured using a synthesis method, for example, a low temperature atomic layer deposition (ALD) process, for example, at or below 250 degrees C. As illustrated in FIG. 18, FeRAM cell 1810 and transistor 1820 are GAA FET. Further, using the high-k dielectric structures increases charge storage capacity and allows thicker dielectric layers to be used.

Although, the memory device shown in FIG. 18A may be configured to as a 1T2C FeRAM having one transistor device 1820 and a 2 bit FeRAM cell 1810, this is not intended to be limiting. It is understood that the memory device in accordance with the disclosure can include one transistor coupled to more than 2 capacitors for increased charge storage capacity, for example, 1T3C, 1T4C, . . . , 1TnC, where n is a positive integer. In some embodiments, they can be implemented in a FinFET structure. In those embodiments, common PLs may be arranged in the FeRAM cell. For example, it is contemplated that, for a 1T3C FeRAM structure, 2 common PLs can be arranged in the 3 bit cell.

As described above, transistor device 1820 includes a channel 1821, interfacial layer, high-k gate dielectric 1822, tungsten gate fill material in conductive electrode layer 1823, and metal interconnect structures 185-1, 185-2, and 185-8 that connect metal layers to the semiconductors. Similarly, the capacitor device 1810 includes a dielectric structure that has an interfacial layer and a high-k gate dielectric, a tungsten gate fill material, and metal contacts.

The channel 1821 for the transistor 1820 can be Si or SiGe, and can be in the shapes of strips, nanosheets, or nanowire structures. The Si or SiGe channel can have at least three nanosheets or nanowires. In some embodiments, the channel length of the topmost Si or SiGe nanosheet is equal to or less than the channel length of the middle Si or SiGe nanosheet, and the channel length of the middle Si or SiGe nanosheet is equal to or less than the channel length of the bottom Si or SiGe nanosheet.

In some embodiments, the dielectric structure layer can include an interfacial layer (IL). In some embodiments, the thickness of the IL on the topmost Si or SiGe nanosheet is greater than the IL on the middle nanosheet, which, in turn, has a thickness that is greater than the IL on the bottom nanosheet. In 3D GAA FeRAM 1810, the dielectric structure 1812 has an HfZrO layer with a thickness equal to or greater than 3 nm, and the Zr concentration is around 40%-60%. However, it is understood that the thickness concentration ranges are only cited as examples, and variations can be made depending on the applications. The dielectric structure layer 1822 in transistor 1820 can be the same as dielectric structure 1812 in FeRAM 1810. Alternatively, the dielectric structure layer 1822 in transistor 1820 can be different than dielectric structure 1812, for example, with HfO2 replacing HfZrO. In some embodiments, the HfZrO and HfO₂ layers can have a crystalline phase, for example, an orthorhombic phase. In some embodiments, the thickness of the dielectric structure layers 1812 and 1822 on the topmost nanosheet is greater than the dielectric structure layers on the middle nanosheet, which, in turn, has a thickness that is greater than the dielectric structure layers on the bottom nanosheet. In some embodiments, during device fabrication, the etching of the dielectric structure layers can be performed using atomic layer etching (ALE) with a control process based on artificial intelligence (A.I.) or machine-learning, as described below with reference to FIG. 25.

The metal gate structures formed by conductive electrode layers 1813 and 1823 for FeRAM 1810 and transistor 1820 can be single layer metal compound or multi-layer metal compound, respectively. In some embodiments, the sheet-sheet spacing can be 8-15 nm for transistor 1820 and 10-20 nm for 3D GAA FeRAM 1810. However, it is understood that the thickness ranges are only cited as examples, and variations can be made depending on the applications. The metal gate structures of the conductive electrode layers can have at least two types of metals. The first is the metal gate with p-type work function, which can include TiN, TaN, WN, and MoN, etc. The second is the metal gate with n-type work function, for example, Al based metals including TiAlC and TaAlC, etc., or metal silicides, including TiSi, TaSi, WSi, CoSi, and NiSi, etc. The metal interconnect structures 185-1 through 185-8 that connect metal layers to the semiconductors can be selected from low-resistance metals besides W, for example, Ru, Ir, Mo, and Co, etc. In some embodiments, the metal contact can include TiSi and/or TiN layers and cobalt fill material. In some embodiments, during device fabrication, the etching of the metal layers can be performed using atomic layer etching (ALE) with a control process based on artificial intelligence (A.I.) or machine-learning, as described below with reference to FIG. 25.

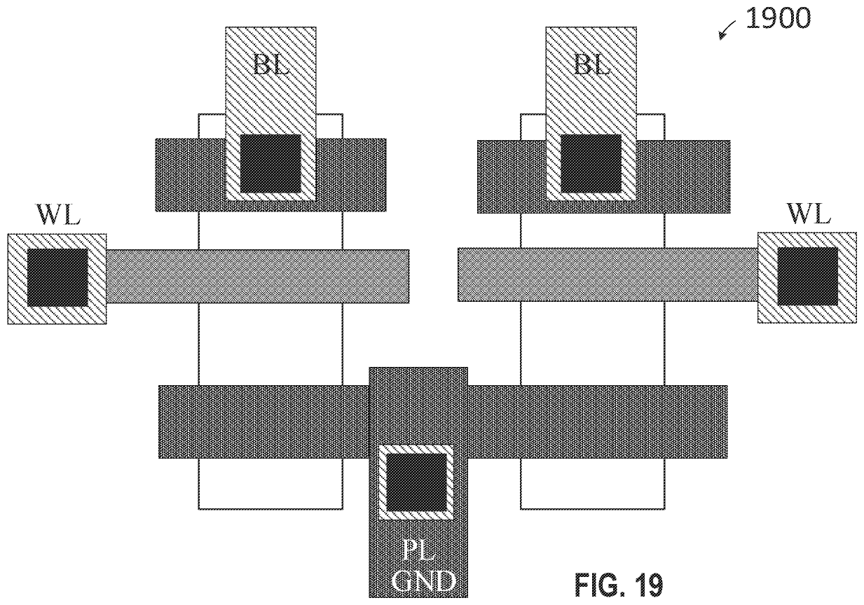

FIG. 19 illustrates a semiconductor device 1900 having a 2 bit FeRAM cell sharing a common PL. FIG. 19 shows a top layout view of the FeRAM cell, which has another arrangement of sharing the PL compared to that shown in FIG. 18B. In implementation, the layout diagram shown in FIG. 19 can be used as a layout for a 2-bit unit cell in an array of FeRAM.

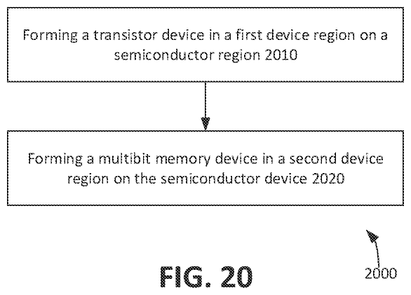

FIG. 20 is a simplified flowchart illustrating a method 2000 of fabricating a semiconductor device, in accordance with some embodiments. In various embodiments, method 2000 describes a method for forming a gate-all-around (GAA) ferromagnetic memory structure and a gate-all-around (GAA) transistor concurrently on the same wafer. It is understood that the GAA capacitor and GAA transistor can also be formed separately. The operations in method 2000 are briefly summarized below with reference to FIGS. 1-19 described above. It is noted that method 2000 as described below may not include all the details to produce a complete semiconductor device. Accordingly, additional processes can be provided before, during, and after method 2000. It is also understood that the operations in method 2000 can be performed in a different order, or some operations not performed, depending on specific applications.

At 2010, a transistor device, such as device 1820 of FIG. 18A, is formed in a first device region on a semiconductor device, such as the memory device of FIG. 18A. Please refer to example embodiments of details of various structures and processing for forming a similar transistor device described in connection with and illustrated by FIGS. 1-19. At 2020, a memory device, such as device 1810 of FIG. 18A, is formed in a second device region on a semiconductor device, such as the memory device of FIG. 18A. Please refer to example embodiments of details of various structures and processing for forming a similar memory device described in connection with and illustrated by FIGS. 1-19.

As illustrated in the examples of FIGS. 1-19, each of forming the transistor device at 2010 and forming the memory device at 2020 include numerous processing steps. In the method 2000, many of the particular steps which are used to form particular portions of the transistor device at 2010, similar to that shown in device region 2 of FIGS. 1-19, are simultaneously used to form similar particular portions of the memory device at 2020, similar to that shown in device region 1 of FIGS. 1-19. In addition, other particular steps performed at 2010 are used to form portions of the transistor device at 2010, and do not contribute to the formation of the memory device. Similarly, other particular steps are used to form portions of the memory device at 2020, and do not contribute to the formation of the transistor device.

One inventive aspect is a method of fabricating a semiconductor device. The method includes forming a transistor device in a first device region on the semiconductor device, and forming a memory device in a second device region on the semiconductor device, the memory device being connected to the transistor device. In some embodiments, forming the memory device includes forming a first bit line, forming a first word line connected to the first bit line, forming a plate line connected to the first word line and the first bit line, forming a second bit line connected to the plate line, and forming a second word line connected to the second bit line and the plate line.

In some embodiments, the memory device includes a ferroelectric material.

In some embodiments, the transistor device is formed side by side with the memory device.

In some embodiments, forming the memory device includes forming first and second stacked structures in the second device regions on a substrate, respectively, each of the first and second stacked structures including a stack of alternating first and second semiconductor strips. In some embodiments, forming the memory device includes removing the first semiconductor strips to form first voids between the second semiconductor strips in both the first and second device regions, and depositing a first dielectric structure layer and a second dielectric structure layer in the first voids to surround the second semiconductor strips in the first and second device regions, respectively, where the first dielectric structure layer is different from the second dielectric layer. In some embodiments, the method incudes depositing a first conductive fill material in the first voids over the first dielectric structure layer and the second dielectric structure layer to surround the second semiconductor strips in the first and second device regions, respectively, in the first device region, removing the second semiconductor strips between portions of the first dielectric structure layer to form second voids, and in the first device region, depositing a second conductive fill material in the second voids between portions of the first dielectric structure layer.

In some embodiments, the first conductive fill material and the second conductive fill material form first and second electrodes of the memory device in the second device region.

In some embodiments, removing the first semiconductor strips to form first voids further includes removing portions of the second semiconductor strips to form recessed regions, depositing a dielectric material in the recessed regions, and removing the first semiconductor strips, using the dielectric material in the recessed regions as a mask, to form the first voids between the second semiconductor strips in the first stacked structure.

In some embodiments, depositing a first dielectric structure layer to surround the second semiconductor strips further includes depositing a first ferroelectric material layer to surround the second semiconductor strips.

Another inventive aspect is a method of fabricating a semiconductor device. The method includes forming a first memory device, where forming the first memory device includes forming a first plurality of ferroelectric channel regions on a semiconductor substrate, forming a plurality of gate structures, each surrounding one of the ferroelectric channel regions, electrically connecting the gate structures to a gate electrode, electrically connecting the channel regions to a source electrode, and electrically connecting the channel regions to a drain electrode.

In some embodiments, the method also includes forming a second device in a first device region of the semiconductor substrate, where the first memory device is formed in a second device region of the semiconductor substrate.

In some embodiments, the second device is a transistor formed side by side with the first memory device.

In some embodiments, the method also includes forming first and second stacked structures in the first and second device regions on the semiconductor substrate, each of the first and second stacked structures including a stack of alternating first and second semiconductor strips, removing the first semiconductor strips to form first voids between the second semiconductor strips in both the first and second device regions, depositing a first dielectric structure layer and a second dielectric structure layer in the first voids to surround the second semiconductor strips in the first and second device regions, respectively, where the first dielectric structure layer is different from the second dielectric structure layer. The method also includes depositing a first conductive fill material in the first voids over the first dielectric structure layer and the second dielectric structure layer to surround the second semiconductor strips in the first and second device regions, respectively, in the first device region, removing the second semiconductor strips between portions of the first dielectric structure layer to form second voids, and in the first device region, depositing a second semiconductor material in the second voids between portions of the first dielectric structure layer.

In some embodiments, the first conductive fill material forms a plurality of electrodes of the second device in the first device region and a plurality of electrodes of the first memory device in the second device region.

In some embodiments, removing the first semiconductor strips to form first voids further includes removing portions of the second semiconductor strips to form recessed regions, depositing a dielectric material in the recessed regions, and removing the first semiconductor strips, using the dielectric material in the recessed regions as a mask, to form the first voids between the second semiconductor strips in the first stacked structure.

In some embodiments, depositing the first dielectric structure layer to surround the second semiconductor strips further includes depositing a first ferroelectric material layer to surround the second semiconductor strips in the first device region.

Another inventive aspect is a method of fabricating a semiconductor device. The method includes forming a first memory device, where forming the first memory device includes forming a plurality of first ferroelectric channel regions on a semiconductor substrate, the first ferroelectric channel regions connecting a first drain region to a source region, forming a plurality of first gate structures, each surrounding one of the first ferroelectric channel regions, forming a second memory device, where forming the second memory device includes forming a plurality of second ferroelectric channel regions on the semiconductor substrate, the second ferroelectric channel regions connecting a second drain region to the source region, forming a plurality of second gate structures, each surrounding one of the second ferroelectric channel regions, electrically connecting the first drain region to a first electrode, electrically connecting the first gate structures to a second electrode, electrically connecting the source region to a third electrode, electrically connecting the second gate structures to the second electrode, and electrically connecting the second drain region to a fourth electrode.

In some embodiments, the first electrode is a first bit line.

In some embodiments, the second electrode is a word line.

In some embodiments, the third electrode is a plate line.

In some embodiments, the fourth electrode is a second bit line.

In some embodiments, the first and second memory devices each have a gate all around transistor structure having a ferroelectric channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of fabricating a semiconductor device, the method comprising:
forming a transistor device in a first device region on the semiconductor device; and
forming a memory device in a second device region on the semiconductor device, the memory device connected to the transistor device; and, wherein forming the memory device comprises:
forming a first bit line;
forming a first word line connected to the first bit line;
forming a plate line connected to the first word line and the first bit line;
forming a second bit line connected to the plate line; and
forming a second word line connected to the second bit line and the plate line.

2. The method of claim 1, wherein the memory device comprises a ferroelectric material.

3. The method of claim 1, wherein the transistor device is formed side by side with the memory device.

4. The method of claim 1, wherein forming the memory device comprises:
forming first and second stacked structures in the second device regions on a substrate, respectively, each of the first and second stacked structures comprising a stack of alternating first and second semiconductor strips;
removing the first semiconductor strips to form the first voids between the second semiconductor strips in both the first and second device regions;
depositing a first dielectric structure layer and a second dielectric structure layer in the first voids to surround the second semiconductor strips in the first and second device regions, respectively, wherein the first dielectric structure layer is different from the second dielectric structure layer;
depositing a first conductive fill material in the first voids over the first dielectric structure layer and the second dielectric structure layer to surround the second semiconductor strips in the first and second device regions, respectively;
in the first device region, removing the second semiconductor strips between portions of the first dielectric structure layer to form second voids; and
in the first device region, depositing a second conductive fill material in the second voids between portions of the first dielectric structure layer.

5. The method of claim 4, wherein the first conductive fill material and the second conductive fill material form first and second electrodes of the memory device in the second device region.

6. The method of claim 4, wherein removing the first semiconductor strips to form the first voids further comprises:
removing portions of the second semiconductor strips to form recessed regions;
depositing a dielectric material in the recessed regions; and
removing the first semiconductor strips, using the dielectric material in the recessed regions as a mask, to form the first voids between the second semiconductor strips in the first stacked structure.

7. The method of claim 4, wherein depositing the first dielectric structure layer to surround the second semiconductor strips further comprises:
depositing a first ferroelectric material layer to surround the second semiconductor strips.

8. A method of fabricating a semiconductor device, the method comprising:
forming a first memory device, wherein forming the first memory device comprises:
forming a first plurality of ferroelectric channel regions on a semiconductor substrate;
forming a plurality of gate structures, each surrounding one of the ferroelectric channel regions;
electrically connecting the gate structures to a gate electrode;
electrically connecting the first plurality of ferroelectric channel regions to a source electrode; and
electrically connecting the first plurality of ferroelectric channel regions to a drain electrode.

9. The method of claim 8, further comprising:
forming a second device in a first device region of the semiconductor substrate, wherein the first memory device is formed in a second device region of the semiconductor substrate.

10. The method of claim 9, wherein the second device is a transistor formed side by side with the first memory device.

11. The method of claim 9, further comprising:
forming first and second stacked structures in the first and second device regions on the semiconductor substrate, each of the first and second stacked structures comprising a stack of alternating first and second semiconductor strips;
removing the first semiconductor strips to form the first voids between the second semiconductor strips in both the first and second device regions;
depositing a first dielectric structure layer and a second dielectric structure layer in the first voids to surround the second semiconductor strips in the first and second device regions, respectively, wherein the first dielectric structure layer is different from the second dielectric structure layer; and
depositing a first conductive fill material in the first voids over the first dielectric structure layer and the second dielectric structure layer to surround the second semiconductor strips in the first and second device regions, respectively,
in the first device region, removing the second semiconductor strips between portions of the first dielectric structure layer to form second voids; and
in the first device region, depositing a second semiconductor material in the second voids between portions of the first dielectric structure layer.

12. The method of claim 11, wherein the first conductive fill material forms a plurality of electrodes of the second device in the first device region and a plurality of electrodes of the first memory device in the second device region.

13. The method of claim 11, wherein removing the first semiconductor strips to form the first voids further comprises:
removing portions of the second semiconductor strips to form recessed regions;
depositing a dielectric material in the recessed regions; and
removing the first semiconductor strips, using the dielectric material in the recessed regions as a mask, to form the first voids between the second semiconductor strips in the first stacked structure.

14. The method of claim 11, wherein depositing the first dielectric structure layer to surround the second semiconductor strips further comprises:
depositing a first ferroelectric material layer to surround the second semiconductor strips in the first device region.

15. A method of fabricating a semiconductor device, the method comprising:
forming a first memory device, wherein forming the first memory device comprises:
forming a plurality of first ferroelectric channel regions on a semiconductor substrate, the first ferroelectric channel regions connecting a first drain region to a source region;
forming a plurality of first gate structures, each surrounding one of the first ferroelectric channel regions;
forming a second memory device, wherein forming the second memory device comprises:
forming a plurality of second ferroelectric channel regions on the semiconductor substrate, the second ferroelectric channel regions connecting a second drain region to the source region;
forming a plurality of second gate structures, each surrounding one of the second ferroelectric channel regions;
electrically connecting the first drain region to a first electrode;
electrically connecting the first gate structures to a second electrode;
electrically connecting the source region to a third electrode;
electrically connecting the second gate structures to the second electrode; and
electrically connecting the second drain region to a fourth electrode.

16. The method of claim 15, wherein the first electrode is a first bit line.

17. The method of claim 15, wherein the second electrode is a word line.

18. The method of claim 15, wherein the third electrode is a plate line.

19. The method of claim 15, wherein the fourth electrode is a second bit line.

20. The method of claim 15, wherein the first and second memory devices each have a gate all around transistor structure having a ferroelectric channel.
